(19) United States
(12) Patent Application Publication
(10) Pub. No.: US 2010/0112478 A1
(43) Pub. Date: May 6, 2010

(54) WATER-DEVELOPABLE PHOTOSENSITIVE LITHOGRAPHIC PRINTING PLATE MATERIAL

(75) Inventor: Akira Furukawa, Tokyo (JP)

Correspondence Address: BIRCH STEWART KOLASCH & BIRCH, PO BOX 747, FALLS CHURCH, VA, 22040-0747, US

(73) Assignee: Mitsubishi Paper Mills Limited, Tokyo (JP)

(21) Appl. No.: 12/532,592

(22) PCT Filed: Mar. 21, 2008
(86) PCT No.: PCT/JP2008/055220

§ 371 Date: Sep. 22, 2009

(30) Foreign Application Priority Data
Mar. 23, 2007 (JP) 2007 077357

(51) Int. Cl. G03F 7/004

(52) U.S. Cl. 430/280.1; 430/287.1

(57) ABSTRACT

The present invention provides a highly sensitive photosensitive lithographic printing plate material capable of being used in a CTP system, which allows on-press development and/or development with water and has superior printability. More specifically, the present invention provides a water-developable photosensitive lithographic printing plate material comprising a support; on the support, a hydrophilic layer containing a water-soluble polymer, a crosslinking agent which forms a cross-linking network with the water-soluble polymers, and colloidal silica, wherein the weight ratio of the water-soluble polymer to the colloidal silica is within the range of 1:1 to 1:3; and, on the hydrophilic layer, a photocurable photosensitive layer containing a polymer having a sulfonic acid group and a vinylphenyl group in a side chain wherein the vinylphenyl group is attached to a main chain through a linking group containing a hetero ring, a photopolymerization initiator, and a compound which sensitizes the photopolymerization initiator.

### TECHNICAL FIELD

The present invention relates to a photosensitive lithographic printing plate material developable with water, and more particularly, to a photosensitive lithographic printing plate material that enables images to be formed by a computer-to-plate (CTP) method. More specifically, the present invention relates to a photosensitive lithographic printing plate material that enables images to be formed by exposing with a scanning exposure device that uses for the light source such as a laser diode emitting light in the wavelength range of 750 to 1100 nm or 400 to 430 nm, and then developing with water. In addition, the present invention relates to a photosensitive lithographic printing plate material that enables on-press development with dampening water on a printing press.

### BACKGROUND ART

Computer-to-plate (CTP) technology has been developed in recent years in which digital data generated with a computer is output directly to a printing plate without being output to film. For this technology, various types of platesetters equipped with various types of lasers as output devices as well as photosensitive lithographic printing plates compatible with the platesetters have been actively developed. Various problems and needs relating to development processing have been indicated as important problems and needs on which greater emphasis has been placed accompanying the proliferation of CTP systems. In an ordinary CTP system, a printing plate material is subjected to laser exposure and imaged, after that, the non-image portion is eluted with an alkaline developing solution. Then, the printing plate material is washed with water and subjected to gum coating steps, and then provided for printing. In the CTP method, exposure processing is a completely digital method and printing data is accurately recorded on the surface of the printing plate material, while development processing acts in an analog manner. As a result, the properties of the resulting lithographic printing plate material are not always determined uniformly, and are influenced considerably by various fluctuating factors in the plate making process. For example, dot area ratio and line width may fluctuate due to fluctuations in processing conditions caused by fluctuations in pH of the development processing solution, a decrease in developability due to accumulation of photosensitive layer components in the developing solution, or the like, which may in turn cause scumming during printing or poor printing wear resistance. The extent to which these analog fluctuation factors relating to development processing can be avoided in order to stably produce printed matter is an important issue. Moreover, growing attention has been placed on problems with alkaline developing solutions based on requests for reduced costs of processing solutions and demands to reduce the environmental burden in recent years. As a result, there are growing expectations being placed on so-called processless printing plates that do not require such a developing process.

Studies have recently been conducted on, as an example of a processless printing plate, on-press printing plates, which are developed on the printing press, and, although not strictly considered to be a processless printing plate, chemical-free printing plates that are developed with water, and some of these printing plates are available on markets and are currently in practical use. On-press systems involve removal of the photosensitive layer by supplying dampening water and ink on a printing press, with the dampening water causing swelling of an unexposed area of the photosensitive layer to facilitate removal thereof by ink. Water developable types involve removal of an unexposed area of the photosensitive layer with water, and are preferable since they facilitates confirmation of an image on a plate surface by using a rinsing step prior to printing. Since printing plates developed with water also enable the unexposed photosensitive layer to be easily removed with dampening water, they can also be used as on-press developing types without going through water development.

At present, known examples of processless printing plates include those using inkjet or thermal transfer systems, those using ablation systems as examples of systems using laser light, those of the thermal fusion type, those of the microcapsule type and those of the separating type. Examples of those using an inkjet system or thermal transfer system include the printing plates described in Japanese Unexamined Patent Publication No. 2004-167973 and Japanese Unexamined Patent Publication No. H9-99662. These printing plates have the problem of having inferior quality as compared with systems using laser light as described below. Examples of printing plates using ablation systems as examples of systems using laser light include the printing plates described in Japanese Unexamined Patent Publications Nos. H8-507727, 116-186750, H6-199064, H7-314934, H10-58636 and H10-244773. Problems with ablation types include contamination of optics by debris generated by ablation, a lack of universality because of the need to provide a special cleaning mechanism for removing ablation debris in the device, and inferior productivity due to low sensitivity and the considerable amount of time required for exposure. Examples of printing plates of the thermal fusion type include printing plates using a system that fuses thermal fusible microparticles with heat, which are described in Japanese Patent No. 2938397 and Japanese Unexamined Patent Publications Nos. 2001-88458, 2001-39047, 2004-50616 and 2004-237592. Problems with these printing plates include low sensitivity, and the occurrence of problems with printing wear resistance because of inferior adhesion with the support. Examples of printing plates of the microcapsule type include printing plates using a material having a photopolymerization function as microcapsules or microparticles followed by curing the microcapsules or microparticles by photopolymerization, such as disclosed in Japanese Unexamined Patent Publications Nos. 2002-29162, 2002-46361, 2002-137562 and 2004-66482. Although printing plates of this type have satisfactory sensitivity due to the use of a highly sensitive photopolymerization system, during on-press development, it is necessary to apply ink after allowing dampening water to cover the entire plate surface followed by removing the unexposed area of the photosensitive layer. However, since it is not always possible to easily remove the unexposed area of the photosensitive layer with the wetting mechanisms of various printing presses, there are cases in which it is difficult to remove the unexposed area of the photosensitive layer depending on the type of printing press, thereby resulting in the problem of scumming (adhesion of ink on non-image areas of the printing plates).

Examples of systems belonging to the separating type include methods which comprises providing a photopolymerizable photosensitive layer on a hydrophilic layer, and after exposure, adhering a receptor sheet to the photosensitive layer and transferring the unexposed area onto the receptor sheet to form images composed of the cured photosensitive layer on the hydrophilic layer, as described in Japanese Unexamined Patent Publications Nos. H7-191457, H7-325394 and H10-3166. In these systems, removal of fine dots at the locations of shadows is considered to be difficult. Further, removal of the unexposed area of the photosensitive layer on the hydrophilic layer is inadequate, thereby resulting in the shortcoming of the occurrence of scumming.

Since processless printing plates using laser light as described above typically require high energy with respect to image formation, a near infrared laser diode is used for the exposure light source. In addition, the majority of these plates use an aluminum plate for the substrate. In contrast, a processless printing plate is described in, for example, Japanese Unexamined Patent Publications Nos. 2004-50616 and 2004-237592 (Patent Document 1) in which a hydrophilic layer is formed on a film support and a heat-meltable microparticle (such as wax) layer is provided thereon. Since the plate material can be housed in roll form as a result of using a film for the support of the printing material, the exposure device can be configured to be small and compact, thereby offering the advantage of considerably improving handling ease of the plate material and reducing costs. However, there are various problems in terms of quality performance. According to the aforementioned unexamined patent publications, since the hydrophilic layer is composed of hydrophilic microparticles such as colloidal silica and montmorillonite, and the images consist of heat-melted wax, adhesion at the interface of the wax and the hydrophilic layer is inadequate, thereby resulting in the problems of inferior printing wear resistance and comparatively low sensitivity.

Moreover, in the case of using for the hydrophilic layer a porous layer comprising silica for the main constituent thereof such as described in Japanese Unexamined Patent Publications Nos. 2004-167973 (Patent Document 2) and H9-99662 (Patent Document 3), ink becomes embedded in gaps between the silica particles during printing thereby resulting in the occurrence of scumming. Alternatively, in the case of attempting use a material after storing for a long period of time, the image forming layer similarly becomes embedded between the particles or becomes adsorbed thereto, thereby causing the formation of a residual layer and potentially leading to the occurrence of scumming as a result thereof.

Japanese Unexamined Patent Publication No. 2000-158839 (Patent Document 4) indicates that favorable results are obtained for ink desorption by forming on a film support a hydrophilic layer containing a water-soluble polymer having a carboxyl group such as polyacrylic acid and colloidal silica at a specific ratio. However, since water-soluble polymers such as polyacrylic acid gradually dissolve in the dampening liquid during printing thereby causing swelling of the hydrophilic layer, there was the problem of the hydrophilic layer or image area separating depending on the printing conditions. Moreover, water retention was also clearly inferior as compared with the printing performance of conventional pre-sensitized plates.

CTP printing plates using a blue-violet laser diode emitting in the wavelength region of 400 to 430 nm are preferably used along with CTP printing plates using a near infrared laser as previously described. For example, a blue-violet laser diode is used practically that is capable of continuously oscillating in the wavelength region of 400 to 430 nm by using an InGaN-based material. Since a laser diode can be produced inexpensively because of their structure, scanning exposure systems using such a blue-violet laser diode offer the advantage of allowing the construction of CTP systems having high economy and productivity while still maintaining an adequate output. Moreover, in comparison with systems using conventional FD-YAG or Ar lasers, these CTP systems offer the advantage of enabling the use of a photosensitive material on which work can be performed under a brighter safe light (under a yellow lamp that cuts off light of 500 nm or lower). Highly sensitive photopolymerization initiators (systems) are used in photopolymerizable compositions using this type of blue-violet laser diode in particular for the light source. Examples of the prior art disclosing systems using titanocene, for example, for the photopolymerization initiator include Japanese Unexamined Patent Publications Nos. H8-272096, 1110-101719, 2000-147763, 2001-42524, 2002-278066, 2003-221517 and 2005-241926. Similarly, examples of systems using a trihalomethyl-substituted triazine derivative for the photopolymerization initiator include those described in Japanese Examined Patent Publication No. S61-9621 and Japanese Unexamined Patent Publication No. 2002-116540. An example of systems using a hexaaryl biimidazole-based compound for the photopolymerization initiator is described in Japanese Unexamined Patent Publication No. 2006-293024. Moreover, an example of a system using a boron salt compound for the photopolymerization initiator is described in Japanese Unexamined Patent Publication No. 2001-290271.

Examples of photosensitive lithographic printing plates of the prior art applied to a CTP system using a blue-violet laser diode with a photopolymerizable compound as described above include the systems described in Japanese Unexamined Patent Publications Nos. 2004-125836, 2005-241926 and 2005-309388. In each of these examples, the printing plate is formed using an alkaline developing solution, and is not a processless or chemical-free printing plate that uses a blue-violet laser diode. Therefore, such a processless or chemical-free printing plate that uses a blue-violet laser diode is currently expected to realize.

Japanese Unexamined Patent Publication No. 2003-215801 (Patent Document 5) discloses a system that uses a cationic or anionic water-soluble polymer in which a vinyl group is attached to a side chain through a phenyl group as a water-developable photosensitive composition, and further discloses that by forming this photosensitive composition on a substrate having a hydrophilic surface, a water-developable printing plate can be produced. In this case, although a silicate-treated aluminum plate or a film support with a hydrophilic undercoating layer are indicated as examples of the support having a hydrophilic surface, regardless of which of these combinations is used, it is difficult to simultaneously satisfy both scumming prevention and printing wear resistance under various printing conditions, thus resulting in the need to conduct studies on materials and compositions for further optimizing these properties. An object of the present invention is to conduct further studies based on Patent Document 5, and to discover an optimal system for achieving both scumming prevention and printing wear resistance.

Patent Document 1: Japanese Unexamined Patent Publication No. 2004-237592

Patent Document 2: Japanese Unexamined Patent Publication No. 2004-167973

Patent Document 3: Japanese Unexamined Patent Publication No. H9-99662

Patent Document 4: Japanese Unexamined Patent Publication No. 2000-158839

Patent Document 5: Japanese Unexamined Patent Publication No. 2003-215801

### DISCLOSURE OF THE INVENTION

### Problems to be Solved by the Invention

An object of the present invention is to provide a highly sensitive photosensitive lithographic printing plate material capable of being used in a CTP system, which allows on-press development and/or development with water and has superior printability.

### Means for Solving the Problems

The aforementioned object of the present invention was achieved by providing a water-developable photosensitive lithographic printing plate material comprising a support; on the support, a hydrophilic layer containing a water-soluble polymer, a crosslinking agent which forms a cross-linking network with the water-soluble polymers, and colloidal silica, wherein the weight ratio of the water-soluble polymer to the colloidal silica is within the range of 1:1 to 1:3; and, on the hydrophilic layer, a photocurable photosensitive layer containing a polymer having a sulfonic acid group and a vinylphenyl group in a side chain wherein the vinylphenyl group is attached to a main chain through a linking group containing a hetero ring, a photopolymerization initiator, and a compound which sensitizes the photopolymerization initiator.

### EFFECTS OF THE INVENTION

According to the present invention, a photosensitive lithographic printing plate material is obtained that can be developed with water and/or on a printing press, and further, a photosensitive lithographic printing plate material is obtained that is free of the occurrence of scumming and has superior printing wear resistance.

### BEST MODE FOR CARRYING OUT THE INVENTION

The following provides a detailed explanation of the present invention. The photosensitive lithographic printing plate material as claimed in the present invention is characterized by comprising:

a support;

on the support, a hydrophilic layer containing a water-soluble polymer, a crosslinking agent which forms a cross-linking network with the water-soluble polymer, and colloidal silica, wherein the weight ratio of the water-soluble polymer to the colloidal silica is within the range of 1:1 to 1:3; and

on the hydrophilic layer, a photocurable photosensitive layer containing:

a polymer having a sulfonic acid group and a vinylphenyl group in a side chain wherein the vinylphenyl group is attached to a main chain through a linking group containing a hetero ring,

a photopolymerization initiator, and

a compound which sensitizes the photopolymerization initiator.

A plastic film and an aluminum support used in the prior art described hereinbelow are preferably used for the support used in the present invention.

The following provides an explanation of the hydrophilic layer used in the present invention. The hydrophilic layer of the present invention contains colloidal silica. As used herein, colloidal silica refers to a colloid of amorphous silica particles, and includes non-denatured colloidal silica, as well as denatured colloidal silica in which the surface of silica has been modified with ions or compounds such as ammonia, calcium and alumina to alter the ionic properties of the particles or alter behavior in response to fluctuations in pH. The silica particles of the colloidal silica used in the hydrophilic layer of the present invention preferably have a mean particle diameter of 5 to 200 nm as measured with a light scattering particle size distribution analyzer, and have various shapes such as spherical, acinar, amorphous or necklaces formed by linking of spherical particles. A silica sol in which these silica particles are stably dispersed in water is used preferably as colloidal silica. Examples of the material of the colloidal silica include various types of colloidal silica such as available under the trade name “Snowtex” from Nissan Chemical Industries, Ltd. Examples of spherical silica sols include Snowtex XS (particle diameter: 4 to 6 nm), Snowtex S (particle diameter: 8 to 11 nm), Snowtex 20 (particle diameter: 10 to 20 nm), Snowtex XL (particle diameter: 40 to 60 nm), Snowtex YL (particle diameter: 50 to 80 nm), Snowtex ZL (particle diameter: 70 to 100 nm) and Snowtex MP-2040 (particle diameter: 200 nm). Examples of acidic silica sols from which sodium salt on the surface has been removed that can be used preferably include Snowtex OXS and Snowtex OS. Examples of acinar and amorphous silica sols include Snowtex UP and Snowtex OUP, and Fine Cataloid F-120 available from Catalysts & Chemicals Industries Co., Ltd. Examples of necklace-like silica sols include Snowtex PS-S (particle diameter: 80 to 120 nm), Snowtex PS-M (particle diameter: 80 to 150 nm) and their acidic types in the form of Snowtex PS-SO and Snowtex PS-MO. Among these, necklace-like silica sols are particularly preferable, and are effective in improving adhesion with a photosensitive layer mentioned hereinbelow, improving printing wear resistance and preventing the occurrence of scumming.

For the colloidal silica contained in the hydrophilic layer, various types of colloidal silica may be used alone, or different types of colloidal silica may be used as a mixture in various ratios. In particular, the use of the aforementioned necklace-like silica sols alone or in combination with spherical colloidal silica having various particle diameters is effective for enhancing coated film strength of the hydrophilic layer and preventing scumming of non-image areas under printing conditions, and allows the obtaining of a preferable system.

The dry solid applied amount of all components in the hydrophilic layer is preferably within the range of 0.5 to 20 g/m² in terms of the dry mass on the support. In the case of being below this range, scumming may occur easily during printing, while in the case of coating in excess of 20 g/m², cracks may form easily in the applied layer. The dry solid applied amount is more preferably within the range of 1 to 10 g/m². The hydrophilic layer is applied to the support and dried using various known coating methods.

Other inorganic microparticles can be added to the hydrophilic layer in addition to the aforementioned colloidal silica. An example of such inorganic microparticles include porous silica microparticles having a mean particle diameter on the micrometer order, specific examples of which include various grades of Sylysia available from Fuji Silysia Chemical, Ltd. The addition of these porous silica microparticles allows the obtaining of preferable effects such as improvement of hydrophilicity and prevention of blocking of the hydrophilic layer. In addition, other examples of inorganic microparticles that can be used include crystalline aluminosilicate known as zeolite, layered clay mineral microparticles in the form of smectite (such as montmorillonite), and talc, and the addition of these inorganic microparticles allows the obtaining of similar preferable effects. In the case of using these porous silica microparticles, zeolite or layered clay mineral microparticles by adding to the hydrophilic layer, they are preferably used at 1 to 10 parts by weight to 100 parts by weight of the colloidal silica. If added in an amount that is less than 1 part by weight, it may be difficult to observe the aforementioned effects, while if added in an amount exceeding 10 parts by weight, the smoothness of the applied layer may be impaired and image quality may decrease, thereby making this undesirable.

In the present invention, the hydrophilic layer is required to contain a water-soluble polymer and a crosslinking agent which forms a cross-linking network with the water-soluble polymer in addition to the colloidal silica. A water-soluble polymer which forms a system that maintains a uniformly dispersed state without causing aggregation of the colloidal silica when mixed with various types of colloidal silica as described above is preferable for the water-soluble polymer used in the present invention, and moreover, a water-soluble polymer that forms a system in which a uniform applied layer is formed without causing phase separation of the colloidal silica and the water-soluble polymer and without giving rise to a porous structure when the applied layer has been formed is more preferable. In order to realize this, an applied material when containing only colloidal silica and the water-soluble polymer preferably has a transparent or slightly turbid, translucent appearance. On the other hand, an applied material containing only colloidal silica and the water-soluble polymer that is turbid and opaque due to phase separation is not preferable in the present invention. Moreover, in the case where an applied material is applied to have formed the hydrophilic layer, the form of the surface of the hydrophilic layer is preferably uniform, and combinations of colloidal silica and water-soluble polymer that cause surface roughness are not preferable. It is essentially important that the water-soluble polymer demonstrate a function that prevents the entrance of ink into the hydrophilic layer during printing by preventing the formation of a porous structure due to the colloidal silica and filling in gaps between the particles, and any water-soluble polymer can be used provided it has this function.

Examples of water-soluble polymers able to be used in the present invention include polyacrylamide, polyvinyl pyrrolidone, polyvinyl alcohol, modified starch and modified cellulose. Moreover, an example of a more preferably water-soluble polymer is a polymer represented by the following general formula I.

A_{X}B_{100-X} General Formula I

In the above formula, X represents the percent by weight of a repeating unit A in a copolymer composition, and represents any value of 1 to 40. The repeating unit A represents a repeating unit having as a reactive group thereof a group selected from the group consisting of a carboxyl group, amino group, hydroxyl group and acetoacetoxy group. The repeating unit B represents a repeating unit having a hydrophilic group required for making the copolymer water-soluble.

It is important that the water-soluble polymer of the general formula I contains in a molecule thereof a reactive group for allowing the crosslinking reaction with a crosslinking agent mentioned hereinbelow to proceed efficiently. Particularly preferable examples of such a reactive group include a carboxyl group, amino group, hydroxyl group and acetoacetoxy group. In order to obtain a water-soluble polymer having these reactive groups in a molecule thereof various types of monomers having reactive groups are preferably copolymerized to allow the reactive groups to be incorporated. Examples of monomers corresponding to the repeating unit A in the general formula I include, but are not limited to, carboxyl group-containing monomers and salts thereof, such as acrylic acid, methacrylic acid, 2-carboxyethyl acrylate, 2-carboxyethyl methacrylate, itaconic acid, crotonic acid, maleic acid, fumaric acid, cinnamic acid, maleic acid monoalkyl ester, fumaric acid monoalkyl ester, 4-carboxystyrene or acrylamide N-glycolic acid; amino group-containing monomers such as allylamine, diallylamine, 2-dimethylaminoethyl acrylate, 2-dimethylaminoethyl methacrylate, 2-diethylaminoethyl acrylate, 2-diethylaminoethyl methacrylate, 3-dimethylaminopropyl acrylamide, 3-dimethylaminopropyl methacrylamide, 4-aminostyrene, 4-aminomethylstyrene, N,N-dimethyl-N-(4-vinylbenzyl)amine or N,N-diethyl-N-(4-vinylbenzyl)amine; nitrogen-containing hetero ring-containing monomers such as 4-vinylpyridine, 2-vinylpyridine or N-vinylimidazole; (meth)acrylamides such as N-methylol acrylamide or 4-hydroxyphenyl acrylamide; hydroxyalkyl (meth)acrylates such as 2-hydroxyethyl acrylate, 2-hydroxyethyl methacrylate, 2-hydroxypropyl acrylate, 2-hydroxypropyl methacrylate or glycerol monomethacrylate; and, acetoacetoxyethyl methacrylate. One type of these monomers having these reactive groups or two or more arbitrary types may be used to compose the repeating unit A.

In the general formula I, X, which represents the proportion (% by weight) of the repeating unit A in the copolymer is preferably within the range of 1 to 40. If below this range, water resistance may be unable to be demonstrated even if the crosslinking reaction proceeds, while if this range is exceeded, the effect resulting from introduction of the repeating unit B for imparting water solubility as described below is diminished, thereby lowering affinity of the hydrophilic layer for water.

Moreover, examples of monomers for yielding the repeating unit B in the general formula I are water-soluble monomers including, but not limited to, sulfo group-containing monomers and salts thereof such as vinylsulfonic acid, allylsulfonic acid, methallylsulfonic acid, styrene sulfonic acid, 2-sulfoethyl methacrylate, 3-sulfopropyl methacrylate or 2-acrylamido-2-methylpropanesulfonic acid; phosphate group-containing monomers and salts thereof such as vinylphosphonic acid; quaternary ammonium salts such as dimethyl diallyl ammonium chloride, acrylic acid-2-(trimethylammonium chloride)ethyl ester, methacrylic acid-2-(trimethylammonium chloride)ethyl ester, acrylic acid-2-(triethylammonium chloride)ethyl ester, methacrylic acid-2-(triethylammonium chloride)ethyl ester, (3-acrylamidopropyl)trimethyl ammonium chloride or N,N,N-trimethyl-N-(4-vinylbenzyl)ammonium chloride; (meth)acrylamides such as acrylamide, methacrylamide, N,N-dimethylacrylamide, N,N-dimethylmethacrylamide, N,N-diethylacrylamide or N-isopropylmethacrylamide; alkyleneoxy group-containing (meth)acrylates such as methoxydiethylene glycol methacrylate monoester, methoxypolyethylene glycol methacrylate mono ester or polypropylene glycol methacrylate monoester; and, N-vinylpyrrolidone or N-vinylcaprolactam. One type of these water-soluble monomers or two or more arbitrary types may be used to compose the repeating unit B.

Preferable examples of water-soluble polymers in the present invention are indicated below.

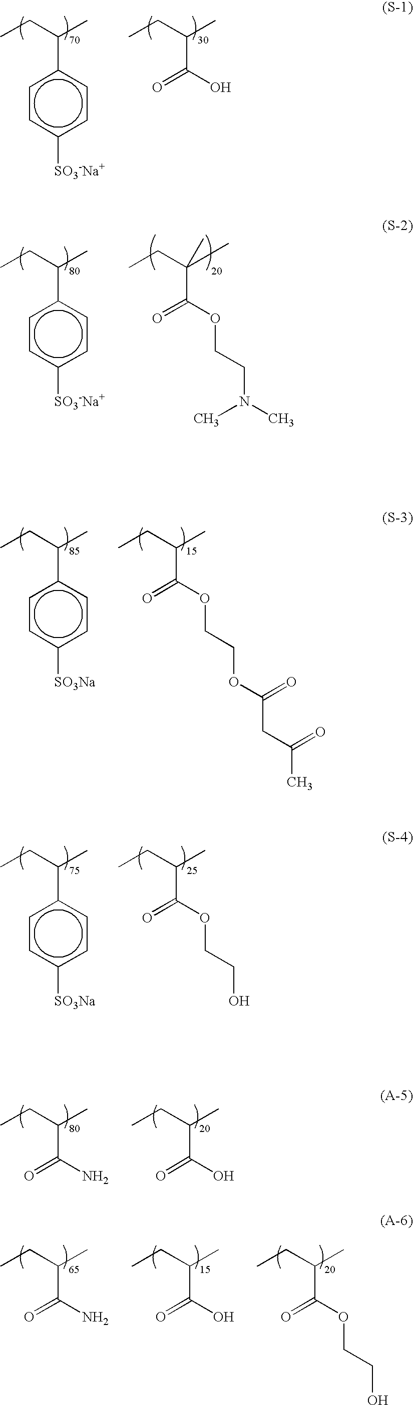

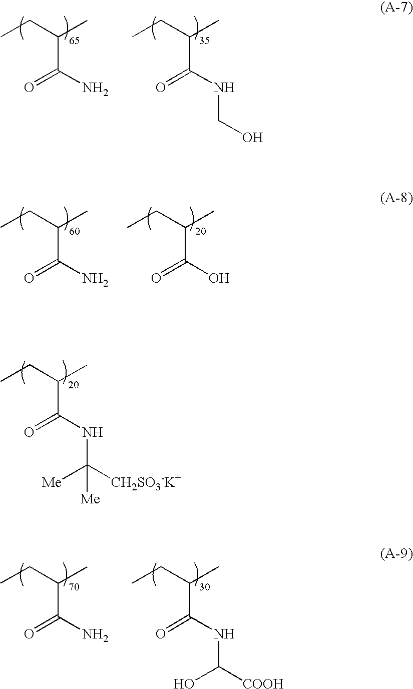

In the case of using these water-soluble polymers in the hydrophilic layer, the weight ratio of the water-soluble polymer to the colloidal silica is preferably within the range of 1:1 to 1:3. In the case the water-soluble polymer is contained in the hydrophilic layer at a ratio with colloidal silica in excess of 1:1, adhesion with the photocurable photosensitive layer mentioned hereinbelow may decrease, thereby resulting in decreased printing wear resistance during printing. In the case the water-soluble polymer is contained in the hydrophilic layer at a ratio with colloidal silica of less than 1:3, although adhesion with the photocurable photosensitive layer is satisfactory and printing wear resistance is adequate, photosensitive layer components may be adsorbed into gaps between the colloidal silica particles, thereby resulting in increased susceptibility to the formation of a residual layer or increased susceptibility to the occurrence of scumming. In addition, scumming may also present a problem during printing depending on the printing conditions. One of the characteristics of the present invention is that the water-soluble polymer is made to be water resistant by forming a crosslinking network with a crosslinking agent mentioned hereinbelow. If the crosslinking agent is not added to the hydrophilic layer, the hydrophilic layer may have inferior water resistance and be separated off during printing in the case of containing the water-soluble polymer within the previously defined range. Satisfactory prevention of scumming is only achieved by containing the crosslinked and water-resistant water-soluble polymer at the ratio described above.

The molecular weight of the water-soluble polymer used in the present invention in terms of the weight average molecular weight is preferably within the range of 10,000 to 1,000,000. In the case the weight average molecular weight is less than 10,000, the mechanical strength of the hydrophilic layer is inadequate and the hydrophilic layer may be separated off during printing. In the case the weight average molecular weight exceeds 1,000,000, the viscosity of the coating solution used when applying the hydrophilic layer becomes excessively high, thereby making application difficult.

The water-soluble polymer of the present invention can be prepared in accordance with known methods. For example, the water-soluble polymer can be prepared by copolymerizing various types of monomers having reactive groups under suitable conditions.

Examples of crosslinking agents added to the hydrophilic layer of the present invention to form a crosslinking network with the water-soluble polymer include various known compounds. More specifically, preferable examples of crosslinking agents include epoxy compounds, aziridine compounds, oxazoline compounds, isocyanate compounds and derivatives thereof, aldehyde compounds such as formalin, methylol compounds and hydrazide compounds. The following provides an explanation of specific examples of these crosslinking agents along with their chemical structures. Epoxy compounds are particularly preferable examples of crosslinking agents.

As used herein, epoxy compounds refer to compounds having two or more epoxy groups in a molecule thereof. A water-soluble epoxy compound is used preferably. Since such epoxy compounds are comparatively stable even in water under neutral to weakly acidic conditions, in the case of preparing a coating solution for forming the hydrophilic layer, the life of the coating solution is long, which is extremely advantageous in continuous production, thereby making this preferable. Preferable examples of epoxy compounds are indicated below.

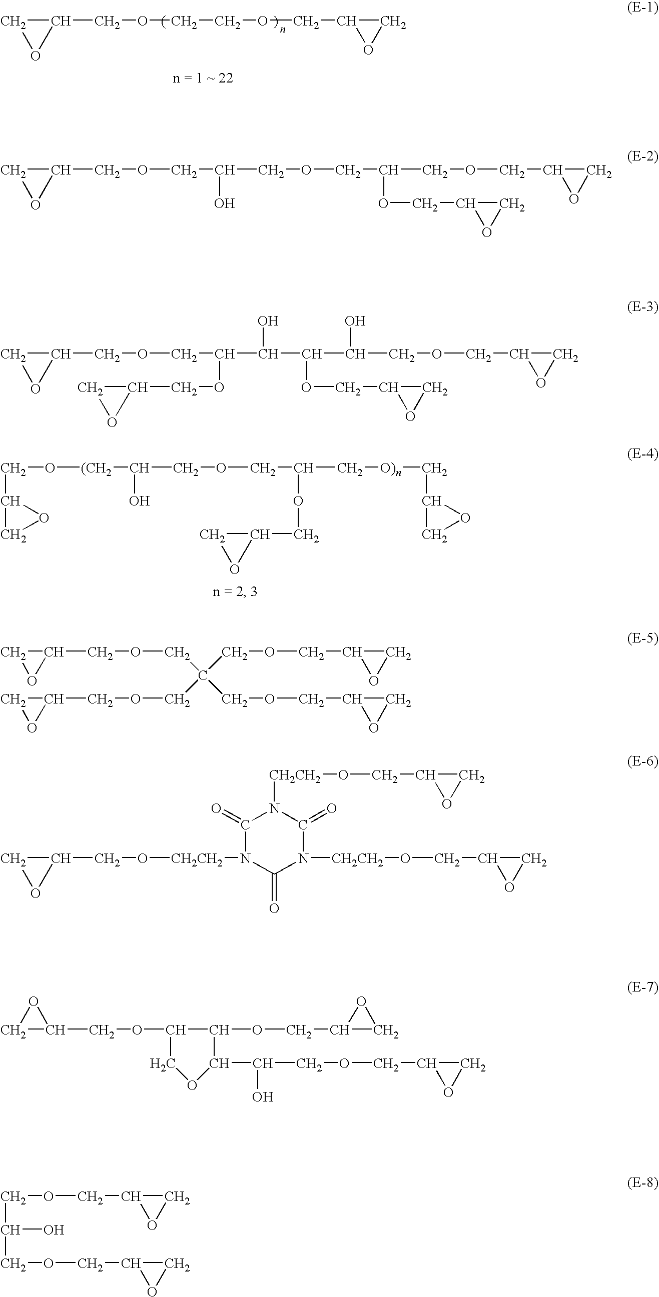

Carboxyl groups and amino groups are particularly preferable as reactive groups contained in the water-soluble polymer for enabling a crosslinking reaction between the epoxy compound as described above and the water-soluble polymer to proceed efficiently. Commercially available products may be used for the epoxy compounds, or those prepared in accordance with known methods may be used.

Preferable examples of compounds used as aziridine compounds are indicated below.

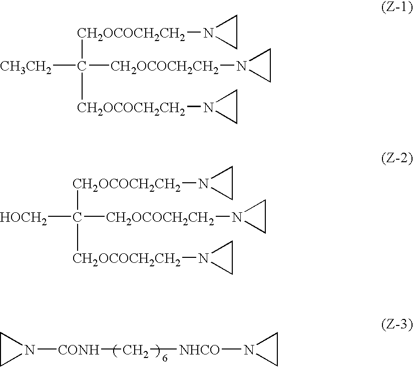

Carboxyl groups are particularly preferable as reactive groups contained in the water-soluble polymer for enabling a crosslinking reaction between such aziridine compounds and the water-soluble polymer to proceed efficiently.

Compounds containing two or more groups represented by the following general formula:

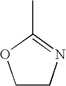

as substituents in a molecule thereof are preferable as oxazoline compounds. Various types of commercially available oxazoline compounds can be used, and examples of those that are used preferably include various grades of compounds commercially available under the trade name “EPOCROS” from Nippon Shokubai Co., Ltd. Carboxyl groups are particularly preferable as reactive groups contained in the water-soluble polymer for enabling a crosslinking reaction between such oxazoline compounds and the water-soluble polymer to proceed efficiently.

Isocyanate compounds that are stable in water are preferable, and so-called self-emulsifying isocyanate compounds and block isocyanate compounds are used preferably. Examples of self-emulsifying isocyanate compounds include self-emulsifying isocyanate compounds like those described in Japanese Examined Patent Publication No. S55-7472 (U.S. Pat. No. 3,996,154), Japanese Unexamined Patent Publication No. H5-222150 (U.S. Pat. No. 5,252,696) and Japanese Unexamined Patent Publications Nos. H9-71720, H9-328654 and H10-60073. More specifically, extremely preferable examples include polyisocyanates having an isocyanurate structure in a molecule thereof that has a cyclic trimer backbone formed from an aliphatic or alicyclic isocyanate, and polyisocyanate compounds having a polyisocyanate having a biuret structure or urethane structure in a molecule thereof for the base polyisocyanate, and which are obtained by adding polyethylene glycol and the like having a single etherified terminal to only a portion of the polyisocyanate groups. The synthesis methods of isocyanate compounds having such structures are described in the references listed above. Specific examples of these self-emulsifying isocyanate compounds are commercially available in the form of compounds having for the base polyisocyanate a polyisocyanate obtained by cyclic trimerization using hexamethylene diisocyanate and the like for the starting material, and examples of which that can be acquired include those available under the name Duranate WB40 or WX1741 from Asahi Kasei Corporation. For block isocyanate compounds, block isocyanates block-polymerized with bisulfites, alcohols, lactams, oximes or active methylenes and the like are used preferably as indicated in, for example, Japanese Unexamined Patent Publications Nos. H4-184335 and H6-175252. Hydroxyl groups and amino groups are particularly preferable as reactive groups contained in the water-soluble polymer for enabling a crosslinking reaction between such isocyanate compounds and the water-soluble polymer to proceed efficiently.

Examples of aldehyde compounds such as formalin and methylol compounds include formalin, glyoxal and various N-methylol compounds as indicated below.

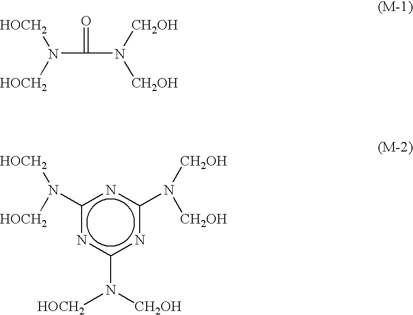

Hydroxyl groups and amino groups are particularly preferable as reactive groups contained in the water-soluble polymer for enabling a crosslinking reaction between such aldehydes or methylol compounds and the water-soluble polymer to proceed efficiently.

Preferable examples of compounds able to be used as hydrazide compounds are indicated below.

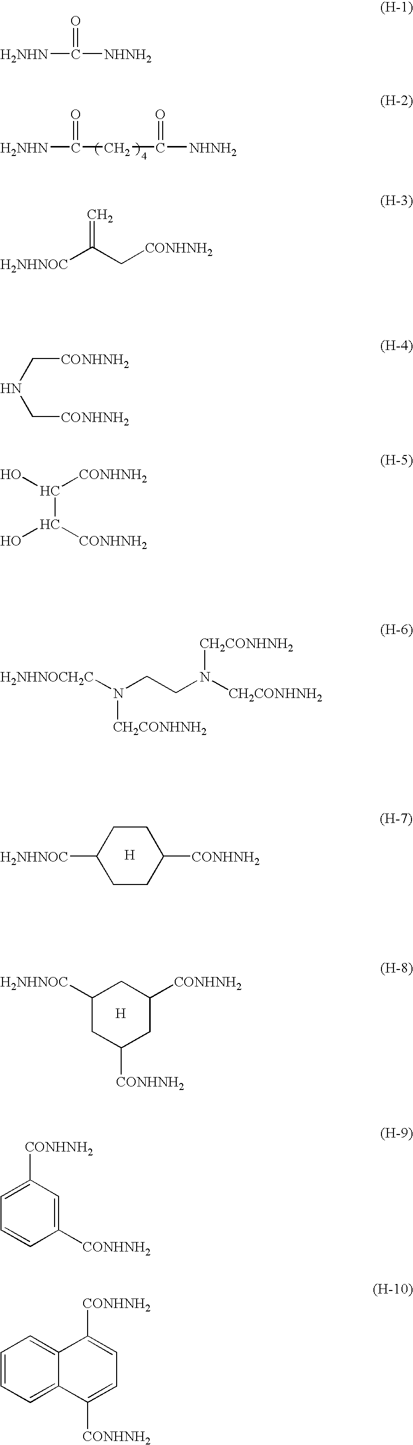

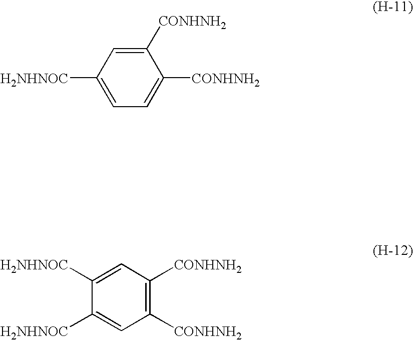

Active methylene groups such as acetoacetoxy groups are particularly preferable as reactive groups contained in the water-soluble polymer for enabling a crosslinking reaction between such hydrazide compounds and the water-soluble polymer to proceed efficiently.

The ratio of the various types of crosslinking agents as described above to the water-soluble polymer is preferably within the range of 1 to 40 parts by weight of crosslinking agent to 100 parts by weight of the water-soluble polymer. If the ratio of crosslinking agent is less than 1 part by weight, water resistance brought about by crosslinking may be inadequate which may cause the occurrence of separation of the hydrophilic layer during printing. On the other hand, if the ratio of crosslinking agent exceeds 40 parts by weight, affinity of the hydrophilic layer for water may decrease thereby causing scumming.

In the present invention, examples of the support on which the hydrophilic layer is provided include various types of plastic films and aluminum plates. Typical examples of plastic film supports include polyethylene terephthalate, polyethylene naphthalate, polyethylene, polypropylene, polystyrene, polyvinyl acetal, polycarbonate, cellulose diacetate, cellulose triacetate, cellulose propionate, cellulose butyrate and cellulose nitrate, with polyethylene terephthalate and polyethylene naphthalate used particularly preferably. The surface of these plastic film supports is preferably subjected to hydrophilic processing prior to providing the hydrophilic layer thereon, and examples of such hydrophilic processing include corona discharge treatment, flame treatment, plasma treatment and ultraviolet radiation treatment. An undercoating layer may also be provided on the plastic film support as additional hydrophilic processing in order to enhance adhesion with the hydrophilic layer to be provided on the plastic film support. A layer having a hydrophilic resin as a main component thereof is effective as an undercoating layer. The hydrophilic resin is preferably a water-soluble resin such as gelatin, gelatin derivatives (such as phthalic gelatin), hydroxyethyl cellulose, carboxymethyl cellulose, methyl cellulose, hydroxypropylmethyl cellulose, ethylhydroxyethyl cellulose, polyvinyl pyrrolidone, polyethylene oxide, xanthane, cationic hydroxyethyl cellulose, polyvinyl alcohol or polyacrylamide. Particularly preferable examples include gelatin and polyvinyl alcohol. Printing wear resistance under long-run printing conditions during large-volume printing is improved by forming a hydrophilic layer on a plastic film support with such an undercoating layer interposed there between, thereby making this preferable.

In the case of using an aluminum plate for the support, an aluminum plate for which the surface has been roughened and which has an anodic oxide coating is used preferably for the purpose of ensuring good adhesion with the hydrophilic layer. Moreover, although an aluminum plate for which the surface thereof has undergone silicate treatment can be used preferably, since hydrophilicity during printing is manifested in the hydrophilic layer obtained in the present invention, hydrophilic treatment in the form of silicate processing of the aluminum surface is not particularly required.

An important point in terms of comparing with the prior art is that by forming the hydrophilic layer obtained in the present invention as described above on the support, adhesion with a photocurable photosensitive layer mentioned hereinbelow becomes extremely good, and as a result, the resulting photosensitive lithographic printing plate material demonstrates high printing wear resistance, as well as favorable water resistance, namely prevention of the occurrence of scumming is achieved. For example, in the case of attempting to use the following hydrophilic resin layers, adhesion with the photocurable photosensitive layer described hereinbelow is inadequate: a hydrophilic resin layer composed of a (meth)acrylate-based polymer having a hydroxyalkyl group as described in Japanese Examined Patent Publication No. S49-2286, a hydrophilic layer composed of a urea resin and a pigment as described in Japanese Examined Patent Publication No. S56-2938, a hydrophilic layer obtained by curing an acrylamide-based polymer with an aldehyde as described in Japanese Unexamined Patent Publication No. S48-83902, a hydrophilic layer obtained by curing a composition containing a water-soluble melamine resin, polyvinyl alcohol and a water-insoluble inorganic powder as described in Japanese Unexamined Patent Publication No. S62-280766, a hydrophilic layer obtained by curing a water-soluble polymer containing a repeating unit containing an amidino group in a side chain as described Japanese Unexamined Patent Publication No. H8-184967, a hydrophilic layer containing a hydrophilic (co)polymer and cured with tetralkylorthosilicate as described in Japanese Unexamined Patent Publication No. H8-272087, a hydrophilic layer having an onium group as described in Japanese Unexamined Patent Publication No. H10-296895, a hydrophilic layer obtained by forming a three-dimensional crosslinking network of a crosslinked hydrophilic polymer having a Lewis base moiety by interaction with a polyvalent metal ion as described in Japanese Unexamined Patent Publication No. H11-311861, or a hydrophilic layer containing a hydrophilic resin and an water-dispersible filler as described in Japanese Unexamined Patent Publication No. 2000-122269. The inventors of the present invention have found that adequate adhesion with a photocurable photosensitive layer is only demonstrated in the presence of a hydrophilic layer containing a water-soluble polymer, a crosslinking agent and colloidal silica as found in the present invention. Specific examples of the hydrophilic layer of the present invention are indicated in Examples hereinbelow.

In the aforementioned Patent Document 5 (Japanese Unexamined Patent Publication No. 2003-215801) in particular, although satisfactory printability was found with respect to lithographic printing plates in which a photocurable photosensitive layer relating to the photocurable photosensitive layer of the present invention was applied to a silicate-treated aluminum support and a film support with a hydrophilic layer composed of a water-soluble polymer being provided, it was difficult to achieve both scumming prevention and printing wear resistance under various conditions such as prevention of the occurrence of scumming and ink elimination after stopping on the printing press or leaving on the plate for a long period of time. One of the characteristics of the present invention is that adequate printing performance was found to be demonstrated for the first time in a combination of a specific photocurable photosensitive layer described below and a hydrophilic layer containing a water-soluble polymer, a crosslinking agent and colloidal silica.

The photocurable photosensitive layer as claimed in the present invention comprises a polymer having a sulfonic acid group and a vinylphenyl group in a side chain, wherein the vinylphenyl group is attached to a main chain through a linking group containing a hetero ring; a photopolymerization initiator; and a compound which sensitizes the photopolymerization initiator. In said polymer, the vinylphenyl group is attached to the polymer main chain through a linking group containing a hetero ring as represented by the following general formula II.

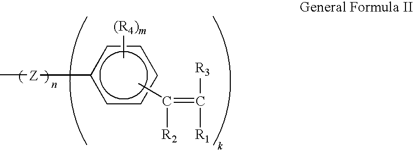

In the formula, Z represents a linking group containing a hetero ring. Examples of the hetero ring include monocyclic or bicyclic hetero rings having 1 to 3 hetero atoms selected from the group consisting of a nitrogen atom, oxygen atom and sulfur atom. Specific examples include nitrogen-containing hetero rings such as a pyrrole ring, pyrazole ring, imidazole ring, triazole ring, tetrazole ring, isoxazole ring, oxazole ring, oxadiazole ring, isothiazole ring, thiazole ring, thiadiazole ring, thiatriazole ring, indole ring, indazole ring, benzimidazole ring, benzotriazole ring, benzoxazole ring, benzthiazole ring, benzoselenazole ring, benzothiadiazole ring, pyridine ring, pyridazine ring, pyrimidine ring, pyrazine ring, triazine ring, quinoline ring or quinoxaline ring, oxygen-containing hetero rings such as a furan ring, and sulfur-containing hetero rings such as a thiophene ring. Moreover, substituents may be attached to these hetero rings. The linking group containing the hetero ring, Z, may contain atoms selected from the group consisting of carbon atoms, nitrogen atoms and sulfur atoms, or may contain a polyvalent group comprised of a group of atoms selected from hydrogen atoms, carbon atoms, nitrogen atoms and sulfur atoms, in addition to the hetero ring. Specific examples of such groups include groups composed of the units exemplified below.

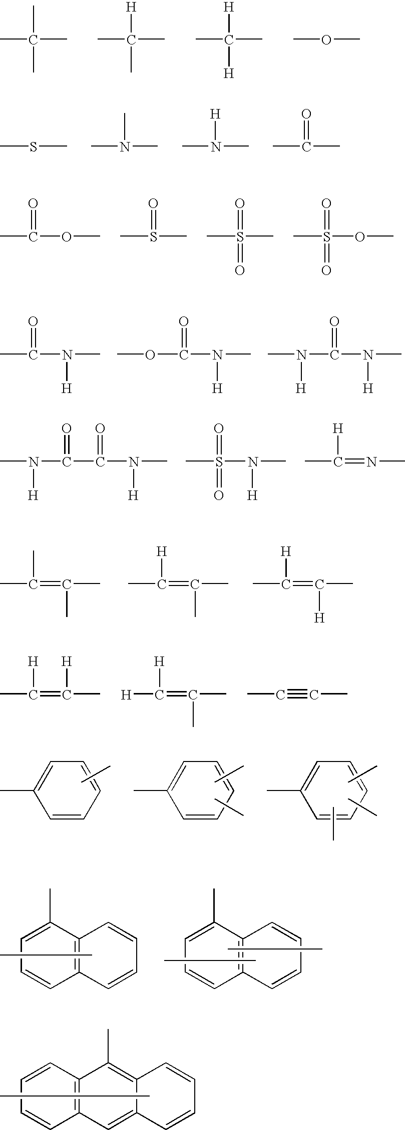

These groups may be present alone or any two or more may be present in combination. Moreover, these groups may also have substituents. R₁, R₂ and R₃ each independently represent a hydrogen atom, halogen atom, carboxy group, sulfo group, nitro group, cyano group, amido group, amino group, alkyl group, aryl group, alkoxy group, or aryloxy group, and these groups may be substituted with groups such as an alkyl group, amino group, aryl group, alkenyl group, carboxy group, sulfo group or hydroxy group. R₄ represents a group or atom able to be substituted with a hydrogen atom, is selected from the group consisting of a halogen atom, carboxy group, sulfo group, nitro group, cyano group, amido group, amino group, alkyl group, aryl group, alkoxy group and aryloxy group, and these groups may be substituted with a group selected from the group consisting of an alkyl group, amino group, aryl group, alkenyl group, carboxy group, sulfo group and hydroxy group. n represents l, m represents an integer of 0 to 4, and k represents an integer of 1 to 4.

Examples of group represented by general formula II include, but are not limited to, the groups indicated below.

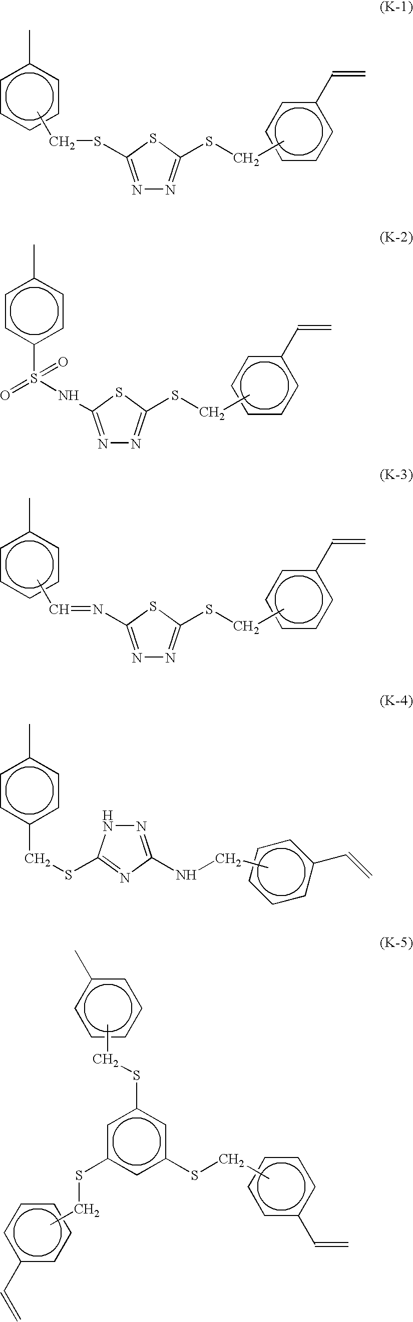

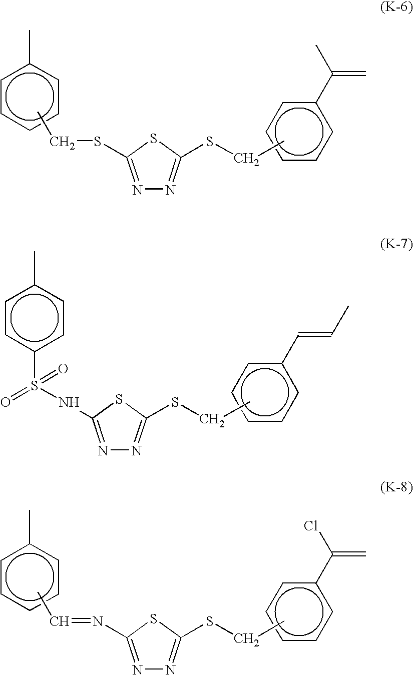

In the groups represented by general formula II indicated above, R₁ and R₂ are preferably hydrogen atoms, and R₃ is preferably a hydrogen atom or a lower alkyl group having up to 4 carbon atoms (such as a methyl group or ethyl group). Moreover, the linking group containing the hetero ring is preferably a linking group containing a thiadiazole ring. k is preferably 1 or 2.

The sulfonic acid group contained in the polymer in combination of the vinylphenyl group is attached to the main chain of the polymer through a linking group L as indicated in general formula III below. The sulfonic acid group is preferably neutralized with an arbitrary base and is in the form of a salt.

-L-SO₃⁻B⁺ General Formula III

In the general formula III above, the linking group L represents an arbitrary atom or group that links the main chain and the sulfonic acid group, and is an atom selected from carbon atoms, nitrogen atoms and sulfur atoms, or a polyvalent linking group composed of a group of atoms selected from hydrogen atoms, carbon atoms, nitrogen atoms and sulfur atoms. Specific examples include groups represented by the following:

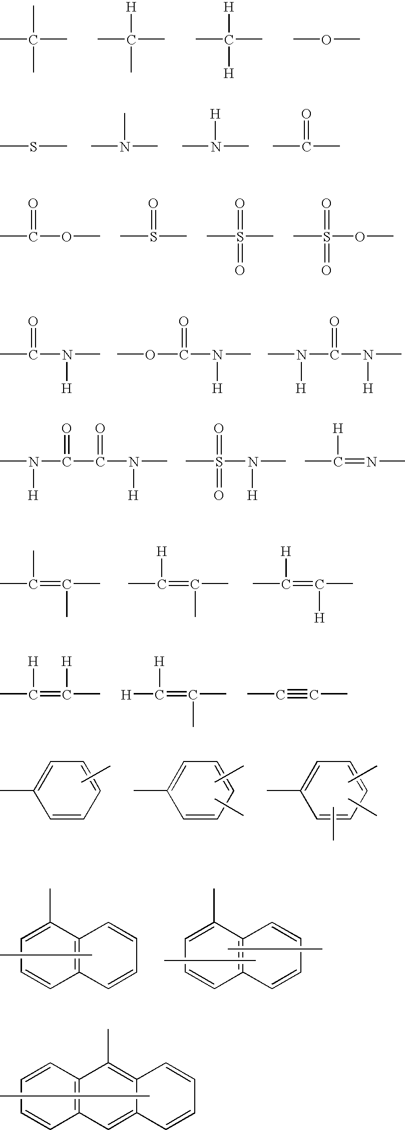

and groups composed of a hetero ring, including nitrogen-containing hetero rings such as a pyrrole ring, pyrazole ring, imidazole ring, triazole ring, tetrazole ring, isoxazole ring, oxazole ring, oxadiazole ring, isothiazole ring, thiazole ring, thiadiazole ring, thiatriazole ring, indole ring, indazole ring, benzimidazole ring, benzotriazole ring, benzoxazole ring, benzthiazole ring, benzoselenazole ring, benzothiadiazole ring, pyridine ring, pyridazine ring, pyrimidine ring, pyrazine ring, triazine ring, quinoline ring or quinoxaline ring, oxygen-containing hetero rings such as a furan ring, and sulfur-containing hetero rings such as a thiophene ring. These groups may be present alone or two or more may be present in combination. Moreover, these groups may have substituents. Particularly preferable examples include an alkylene group and an arylene group. Examples of bases B⁺ that form a salt with the sulfonic acid group and used preferably include inorganic bases such as sodium hydroxide, potassium hydroxide or lithium hydroxide, various types of amines, and quaternary ammonium salts such as tetramethyl ammonium hydroxide, tetrabutyl ammonium hydroxide or choline.

The characteristic of the polymer contained in the photocurable photosensitive layer in the present invention is water-soluble because of allowing water developability. For the ratio of the sulfonic acid group to the vinylphenyl group in the polymer, the repeating units having a sulfonic acid group are preferably within the range of 40% by weight to 90% by weight in the polymer. In the case of being less than 40% by weight, the polymer may become insoluble in water thereby lowering water developability or on-press developability. In the case the ratio exceeds 90% by weight, adequate printing wear resistance may not be obtained. One of the characteristics of the present invention is that both scumming prevention and printing wear resistance have been found to be significantly realized by providing the photocurable photosensitive layer containing a polymer as previously described on the previously described hydrophilic layer containing a water-soluble polymer, a crosslinking agent and colloidal silica. Although the mechanism is thought to particularly involve ionic interaction between sulfonic acid groups in the polymer and silanol groups (and particularly sodium salts) on the surface of the colloidal silica in the hydrophilic layer, this is not completely clear.

A tertiary amine having a hydroxyl group is more preferable for the base used to neutralize the aforementioned sulfonic acid group, specific examples of which include dimethylamino ethanol, diethylaminoethanol, triethanolamine, n-butyldiethanolamine and t-butyldiethanolamine. The use of a polymer in which the sulfonic acid group has been neutralized using these bases results in extremely favorable water developability or on-press developability of the polymer, and is extremely preferable for preventing the occurrence of scumming.

The molecular weight of the aforementioned polymer in terms of the weight average molecular weight is preferably within the range of 5,000 to 200,000. If the weight average molecular weight is less than 5,000, printing wear resistance may become inadequate, while if the weight average molecular weight exceeds 200,000, viscosity of the coating solution during application may become excessively high, thereby making uniform application difficult. The molecular weight is more preferably 10,000 to 200,000 and even more preferably 10,000 to 100,000.

In addition to repeating units having a sulfonic acid group and vinylphenyl group as previously described, various other repeating units can be introduced into the aforementioned polymer composition depending on the specific purpose. Examples of which include repeating units composed of hydrophilic monomers, hydrophobic monomers and any combinations thereof. Examples of such hydrophilic monomers include, but are not limited to, carboxyl group-containing monomers and salts thereof such as acrylic acid, methacrylic acid, 2-carboxyethyl acrylate, 2-carboxyethyl methacrylate, itaconic acid, crotonic acid, maleic acid, fumaric acid, cinnamic acid, maleic acid monoalkyl ester, fumaric acid monoalkyl ester, 4-carboxystyrene or acrylamido-N-glycolic acid; phosphate group-containing monomers and salts thereof such as vinylphosphonic acid; amino group-containing monomers and quaternary ammonium salts thereof such as allylamine, diallylamine, 2-dimethylaminoethyl acrylate, 2-dimethylamino ethyl methacrylate, 2-diethylaminoethyl acrylate, 2-diethylaminoethyl methacrylate, 3-dimethylaminopropyl acrylamide, 3-dimethylaminopropyl methacrylamide, 4-aminostyrene, 4-aminomethylstyrene, N,N-dimethyl-N-(4-vinylbenzyl)amine or N,N-diethyl-N-(4-vinylbenzyl)amine; nitrogen-containing hetero ring-containing monomers and quaternary ammonium salts thereof such as 4-vinylpyridine, 2-vinylpyridine, N-vinylimidazole or N-vinylcarbazole; (meth)acrylamides such as acrylamide, methacrylamide, N,N-dimethylacrylamide, N,N-dimethylmethacrylamide, N,N-diethylacrylamide, N-isopropylmethacrylamide, diacetone acrylamide, N-methylol acrylamide or 4-hydroxylphenylacrylamide; hydroxyalkyl (meth)acrylates such as 2-hydroxyethyl acrylate, 2-hydroxyethyl methacrylate, 2-hydroxypropyl acrylate, 2-hydroxypropyl methacrylate or glycerol mono methacrylate; alkyleneoxy group-containing (meth)acrylates such as methoxydiethylene glycol methacrylate monoester, methoxy polyethylene glycol methacrylate monoester or polypropylene glycol methacrylate monoester; N-vinylpyrrolidone; and, N-vinylcaprolactam. One type of these hydrophilic monomers may be used or two or more arbitrary types may be used.

Examples of hydrophobic monomers include styrene derivatives such as styrene, 4-methylstyrene, 4-hydroxystyrene, 4-acetoxystyrene, 4-chloromethylstyrene or 4-methoxystyrene; alkyl (meth)acrylates such as methyl acrylate, methyl methacrylate, ethyl acrylate, ethyl methacrylate, n-butyl methacrylate, n-hexyl methacrylate, 2-ethylhexyl methacrylate, cyclohexyl acrylate or dodecyl methacrylate; aryl (meth)acrylates or arylalkyl (meth)acrylates such as phenyl methacrylate or benzyl methacrylate; vinyl esters such as acrylonitrile, methacrylonitrile, phenylmaleimide, hydroxyphenylmaleimide, vinyl acetate, vinyl chloroacetate, vinyl propionate, vinyl butyrate, vinyl stearate or vinyl benzoate; vinyl ethers such as methyl vinyl ether or butyl vinyl ether; and various other types of monomers such as acryloyl morpholine, tetrahydrofurfuryl methacrylate, vinyl chloride, vinylidene chloride, allyl alcohol, vinyl trimethoxysilane or glycidyl methacrylate. In addition to the repeating units having a sulfonic acid group and a vinylphenyl group, copolymers composed of repeating units composed of the aforementioned hydrophilic monomers, hydrophobic monomers and any combinations thereof can be used as a polymer in the present invention. In the case a repeating unit other than the repeating unit having a sulfonic acid group and vinylphenyl group is contained in the polymer, the ratio of the repeating unit in the polymer is preferably held to 50% by weight or less of the total. In the case of having been introduced at a ratio in excess of 50% by weight, the object of realizing both scumming prevention and printing wear resistance according to the present invention may be impaired.

Preferable examples of polymers in the present invention are indicated below, but are not limited to these examples. In the formulae, the numbers represent the percent by weight of each repeating unit in the polymer. These polymers are easily synthesized according to methods similar to synthesis examples describe in, for example, Japanese Unexamined Patent Publication No. 2003-215801.

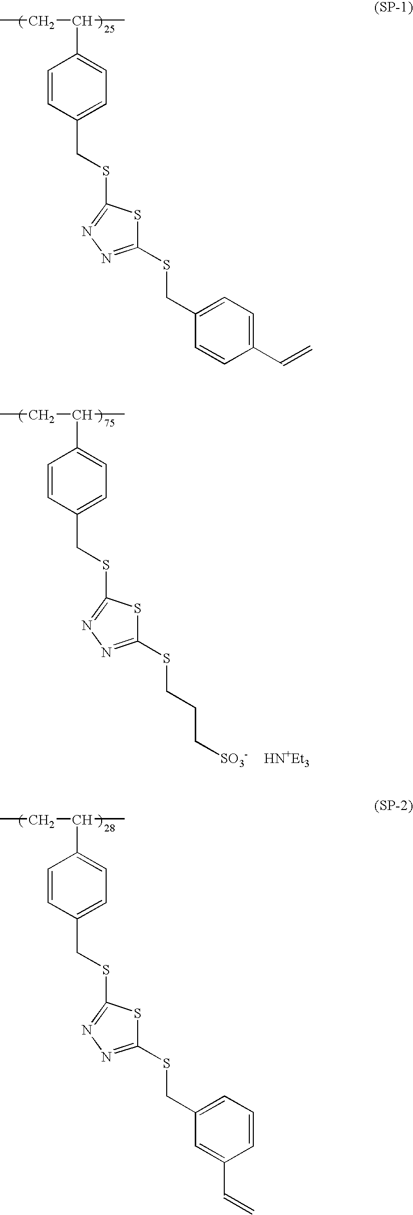

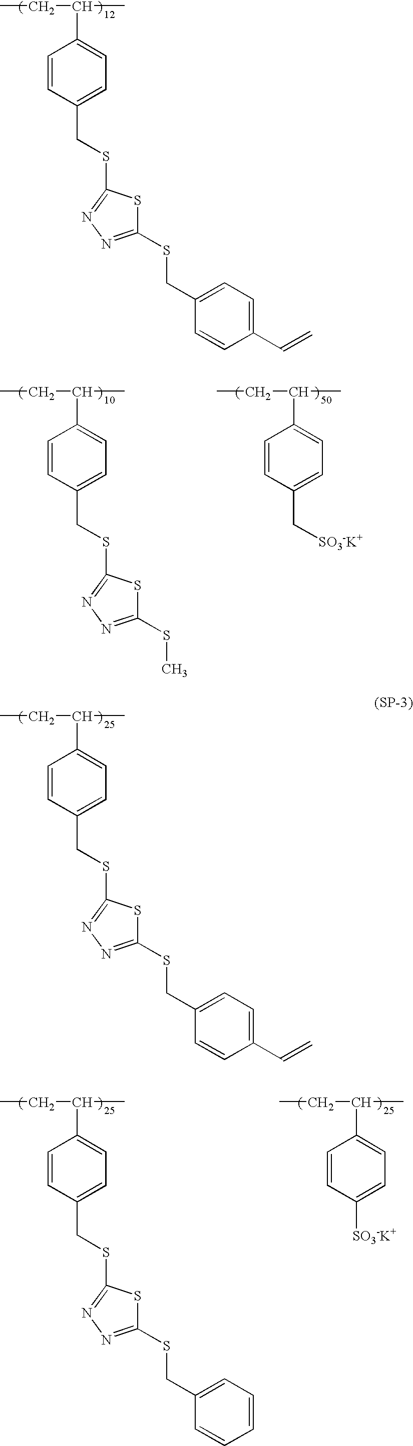

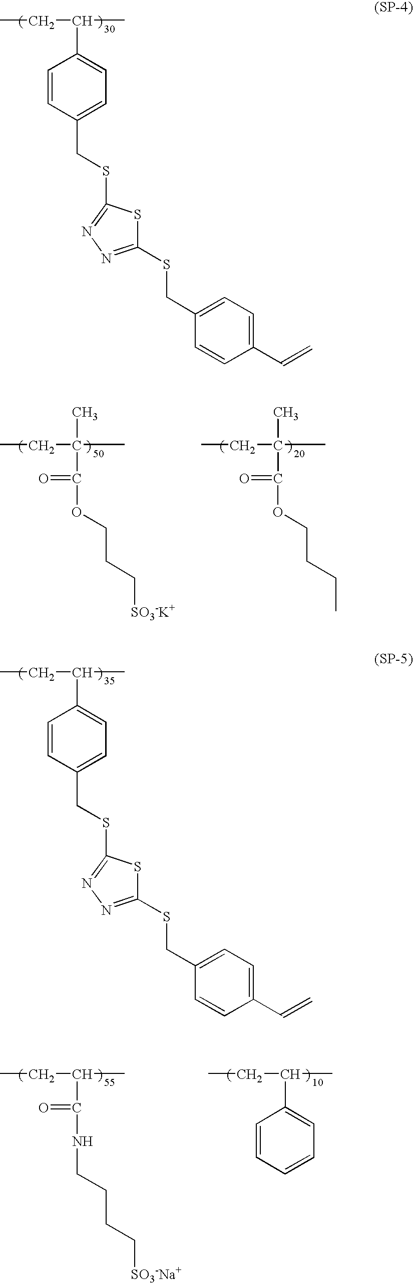

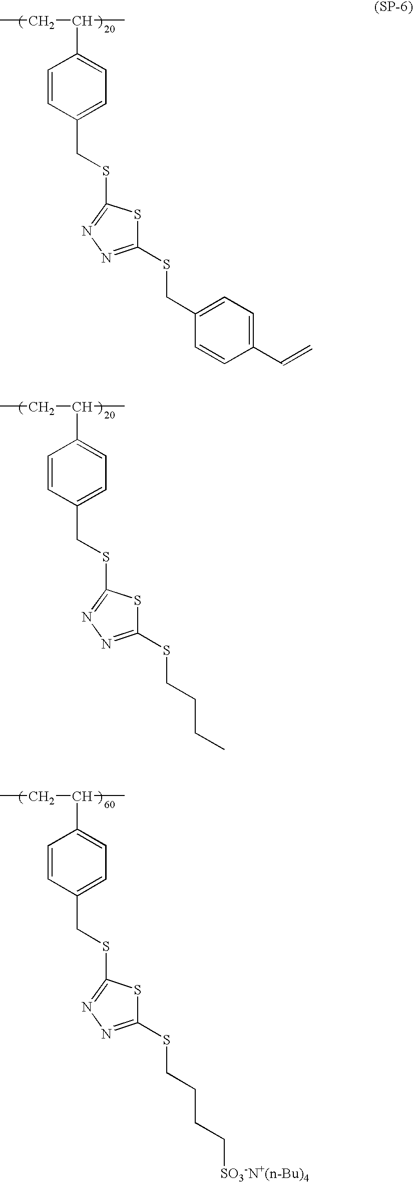

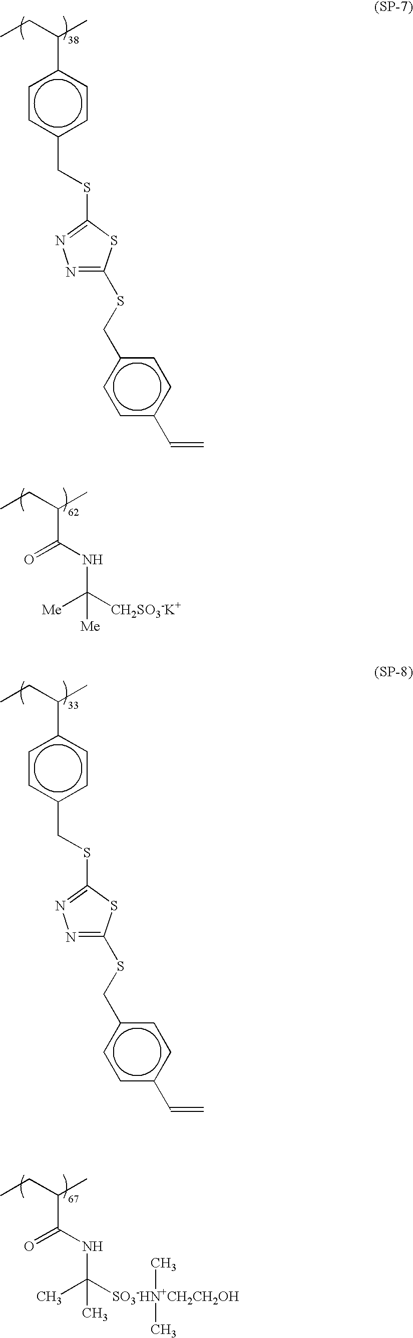

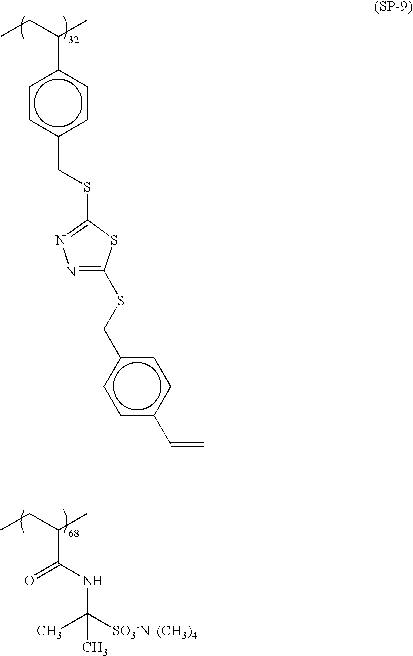

The photocurable photosensitive layer as claimed in the present invention contains a photopolymerization initiator along with the polymer. Any arbitrary compound can be used for the photopolymerization initiator used in the present invention provided it is a compound that is able to generate radicals by irradiation with light or an electron beam.

Examples of photopolymerization initiators able to be used in the present invention include (a) aromatic ketones, (b) aromatic onium salt compounds, (c) organic peroxides, (d) hexaaryl biimidazole compounds, (e) ketoxime ester compounds, (f) azinium compounds, (g) active ester compounds, (h) metallocene compounds, (i) trihaloalkyl-substituted compounds, and (j) organic boron salt compounds.

Preferable examples of the (a) organic ketones include compounds having a benzophenone backbone or thioxanthone backbone described in “Radiation Curing in Polymer Science and Technology”, J. P. Fouassier, J. F. Rabek (1993), p. 77-177, α-thiobenzophenone compounds described in Japanese Examined Patent Publication No. S47-6416, benzoin ether compounds described in Japanese Examined Patent Publication No. S47-3981, α-substituted benzoin compounds described in Japanese Examined Patent Publication No. S47-22326, benzoin derivatives described in Japanese Examined Patent Publication No. S47-23664, alloyl phosphonic acid esters described in Japanese Unexamined Patent Publication No. S57-30704, dialkoxybenzophenones described in Japanese Examined Patent Publication No. S60-26483, benzoin ethers described in Japanese Examined Patent Publication No. S60-26403 and Japanese Unexamined Patent Publication No. S62-81345, p-di(dimethylaminobenzoyl)benzene described in Japanese Unexamined Patent Publication No. H2-211452, thio-substituted aromatic ketones described in Japanese Unexamined Patent Publication No. S61-194062, acylphosphine sulfide described in Japanese Examined Patent Publication No. H2-9597, acylphosphines described in Japanese Examined Patent Publication No. H2-9596, thioxanthones described in Japanese Examined Patent Publication No. S63-61950 and coumarins described in Japanese Examined Patent Publication No. S59-42864.

Examples of the (b) aromatic onium salt compounds include aromatic onium salts of N, P, As, Sb, Bi, O, S, Sc, Tc or I. Specific examples of such aromatic onium salts include the compounds exemplified in Japanese Examined Patent Publications Nos. S52-14277, S52-14278 and S52-14279.

Examples of the (c) organic peroxides include nearly all organic compounds having one or more oxygen-oxygen bond(s) in a molecule thereof, preferable examples of which include peroxide esters such as 3,3′,4,4′-tetra-(tert-butylperoxycarbonyl)benzophenone, 3,3′,4,4′-tetra-(tert-amylperoxycarbonyl)benzophenone, 3,3′,4,4′-tetra(tert-hexylperoxycarbonyl)benzophenone, 3,3′,4,4′-tetra-(tert-octylperoxycarbonyl)benzophenone, 3,3′,4,4′-tetra-(cumylperoxycarbonyl)benzophenone, 3,3′,4,4′-tetra-(p-isopropylcumylperoxycarbonyl)benzophenone or di-tert-butyldiperoxyisophthalate.

Examples of the (d) hexaaryl biimidazole compounds include lophine dimers described in Japanese Examined Patent Publications Nos. S45-37377 and S44-86516, such as 2,2′-bis(o-chlorophenyl)-4,4′,5,5′-tetraphenyl biimidazole, 2,2′-bis(o-bromophenyl)-4,4′,5,5′-tetraphenyl biimidazole, 2,2′-bis(o,p-dichlorophenyl)-4,4′,5,5′-tetraphenyl biimidazole, 2,2′-bis(o-chlorophenyl)-4,4′,5,5′-tetra(m-methoxyphenyl)biimidazole, 2,2′-bis(o,o′-dichlorophenyl)-4,4′,5,5′-tetraphenyl biimidazole, 2,2′-bis(o-nitrophenyl)-4,4′,5,5′-tetraphenyl biimidazole, 2,2′-bis(o-methylphenyl)-4,4′,5,5′-tetraphenyl biimidazole or 2,2′-bis(o-trifluoromethylphenyl)-4,4′,5,5′-tetraphenyl biimidazole.

Examples of the (e) ketoxime ester compounds include 3-benzoyloxyiminobutan-2-one, 3-acetoxyiminobutan-2-one, 3-propionyloxyiminobutan-2-one, 2-acetoxyiminopentan-3-one, 2-acetoxyimino-1-phenylpropan-1-one, 2-benzoyloxyimino-1-phenylpropan-1-one, 3-p-toluenesulfonyloxyiminobutan-2-one and 2-ethoxycarbonyloxyimino-1-phenylpropan-1-one.

Examples of the (f) azinium salt compounds include a group of compounds having N—O bond(s) described in, for example, Japanese Unexamined Patent Publication Nos. S63-138345, S63-142345, S63-142346, S63-143537 and Japanese Examined Patent Publication No. S46-42363.

Examples of the (g) active ester compounds include imidosulfonate compounds described in Japanese Examined Patent Publication No. S62-6223, and active sulfonates described in Japanese Examined Patent Publication No. S63-14340 and Japanese Unexamined Patent Publication No. S59-174831.

Examples of the (h) metallocene compounds include titanocene compounds described in, for example, Japanese Unexamined Patent Publications Nos. S59-152396, S61-151197, S63-41484, H2-249 and H2-4705, and iron arene complexes described in, for example, Japanese Unexamined Patent Publications Nos. H1-304453 and H1-152109. Specific examples of titanocene compounds include dicyclopentadienyl-Ti-dichloride, dicyclopentadienyl-Ti-bis-phenyl, dicyclopentadienyl-Ti-bis-2,3,4,5,6-pentafluorophen-1-yl, dicyclopentadienyl-Ti-bis-2,3,5,6-tetrafluorophen-1-yl, dichloropentadienyl-Ti-bis-2,4,6-trifluorophen-1-yl, dicyclopentadienyl-Ti-2,6-difluorophen-1-yl, dicyclopentadienyl-Ti-bis-2,4-difluorophen-1-yl, dimethylcyclopentadienyl-Ti-bis-2,3,4,5,6-pentafluorophen-1-yl, dimethylcyclopentadienyl-Ti-bis-2,6-difluorophen-1-yl and dicyclopentadienyl-Ti-bis-2,6-difluoro-3-(pyl-1-yl)-phen-1-yl.

Examples of the (i) trihaloalkyl-substituted compounds specifically include compounds having at least one trihaloalkyl group such as a trichloromethyl group or tribromomethyl group in a molecule thereof, such as trihalomethyl-s-triazine compounds described in, for example, U.S. Pat. Nos. 3,954,475, 3,987,037, 4,189,323, Japanese Unexamined Patent Publications Nos. S61-151644, S63-298339 or H4-69661, H11-153859, or 2-trihalomethyl-1,3,4-oxadiazole derivatives described in, for example, Japanese Unexamined Patent Publications Nos. S54-74728, S55-77742, S60-138539, S61-143748, H4-362644 or H11-84649. In addition, the trihaloalkyl group may be attached to an aromatic ring or a nitrogen-containing hetero ring through a sulfonyl group, examples of which include trihaloalkylsulfonyl compounds described in, for example, Japanese Unexamined Patent Publication No. 2001-290271.

Examples of the (j) organic boron salt compounds include organic boron ammonium compounds described in, for example, Japanese Unexamined Patent Publications Nos. H8-217813, H9-106242, H9-188685, 119-188686 or H9-188710; organic boron sulfonium compounds and organic boron oxosulfonium compounds described in, for example, Japanese Unexamined Patent Publications Nos. H6-175561, H6-175564 or H6-157623; organic boron iodonium compounds described in, for example, Japanese Unexamined Patent Publications Nos. H6-175553 or H6-175554, organic boron phosphonium compounds described in, for example, Japanese Unexamined Patent Publication No. H9-188710; and, organic boron transition metal ligand complexes described in, for example, Japanese Unexamined Patent Publications Nos. H6-348011, H7-128785, H7-140589, H7-292014 or H7-306527. Additional examples include cationic pigments containing counter anions in the form of organic boron anions described in, for example, Japanese Unexamined Patent Publications Nos. S62-143044 and H5-194619.

In the case of reacting the photocurable photosensitive layer of the present invention by exposing to blue-violet light in the wavelength region of 400 to 430 nm, the (d) hexaaryl biimidazole compounds, the (h) metallocene compounds, the (i) trihaloalkyl-substituted compounds or the (j) organic boron salt compounds are used particularly preferably for the photopolymerization initiator.

In the case of reacting the photocurable photosensitive layer of the present invention by exposing to near infrared to infrared light in the wavelength region of 750 nm or higher, the (i) trihaloalkyl-substituted compounds or the (j) organic boron salt compounds are used particularly preferably for the photopolymerization initiator.

The aforementioned photopolymerization initiator may be used alone or two or more arbitrary types may be used in combination. In the case of using the (i) trihaloalkyl-substituted compounds and the (j) organic boron salt compounds in combination in particular, sensitivity improves considerably, thereby making this preferable. The content of the photopolymerization initiator in the photocurable photosensitive layer is preferably within the range of 1 to 100% by weight based on the polymer and particularly preferably within the range of 1 to 40% by weight.

The (j) organic boron salt compounds are used particularly preferably for the photopolymerization initiator as claimed in the present invention. More preferably, the (j) organic boron salt compounds and the (i) trihaloalkyl-substituted compounds (such as an s-triazine compound and an oxadiazole derivative as a trihaloalkyl-substituted nitrogen-containing hetero ring compound, or a trihaloalkyl sulfonyl compound) are used in combination.

The organic boron anion that composes the (j) organic boron salt compounds is represented by the following general formula IV.

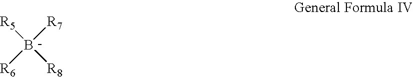

In this formula, R₅, R₆, R₇ and R₈ may be respectively the same or different, and represent an alkyl group, aryl group, aralkyl group, alkenyl group, alkynyl group, cycloalkyl group or heterocyclic group. Among these, those wherein one of R₅, R₆, R₇ and R₈ is an alkyl group and the other substituents are aryl groups is particularly preferable.

The aforementioned organic boron anion is present with a cation that forms a salt therewith. Examples of cations in this case include alkaline metal ions, onium ions and cationic sensitizing pigments. Examples of onium ions include ammonium ions, sulfonium ions, iodinium ions and phosphonium ion compounds. In the case of using a salt of an alkaline metal ion or an onium ion with an organic boron anion, an additional sensitizing pigment is added to impart photosensitivity in the wavelength range of light absorbed by the pigment. In the case of using a salt of a cationic sensitizing pigment with an organic boron anion, photosensitivity is imparted corresponding to the absorption wavelength of the sensitizing pigment. However, in the latter case of using the cationic sensitizing pigment, an alkaline metal ion or onium ion is preferably contained in combination as a counter cation of the organic boron anion.

A salt of the organic boron anion of the general formula IV above with alkaline metal ion and onium ion as a counter cation is preferably used for the (j) organic boron salt compounds used in the present invention. Particularly preferable examples include salts of an organic boron anion and an onium ion (onium salt), including ammonium salts such as tetraalkylammonium salts, sulfonium salts such as triaryl sulfonium salts and phosphonium salts such as triarylalkyl phosphonium salts. Particularly preferable examples of organic boron salt compounds are indicated below.

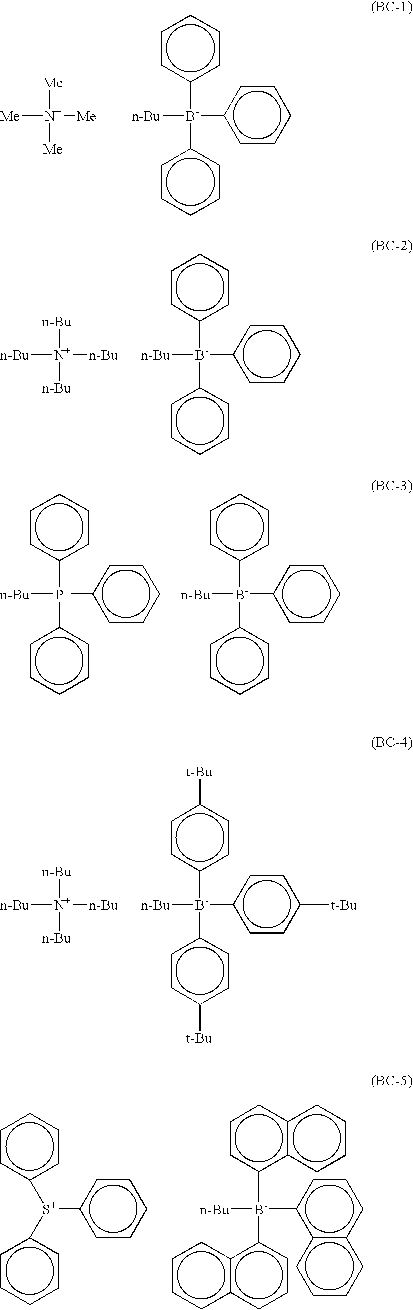

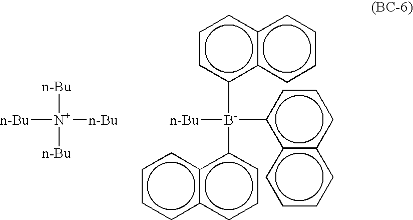

In the present invention, the use of an (j) organic boron salt compound and a (i) trihaloalkyl-substituted compound in combination for the photopolymerization initiator results in higher sensitivity and higher contrast of the photocurable photosensitive layer. The (i) trihaloalkyl-substituted compounds specifically refer to compounds having at least one trihaloalkyl group such as a trichloromethyl group or tribromomethyl group in a molecule thereof, and preferable examples thereof include s-triazine derivatives and oxadiazole derivatives that are compounds containing a nitrogen-containing heterocyclic group substituted with the trihaloalkyl group, or aromatic ring or nitrogen-containing heterocyclic compounds containing a trihaloalkyl sulfonyl group, which are compounds in which the trihaloalkyl group is attached to an aromatic ring or a nitrogen-containing hetero ring through a sulfonyl group.

Particularly preferable examples of compounds containing a nitrogen-containing heterocyclic group substituted with a trihaloalkyl group and compounds containing a trihaloalkyl sulfonyl group are indicated below.

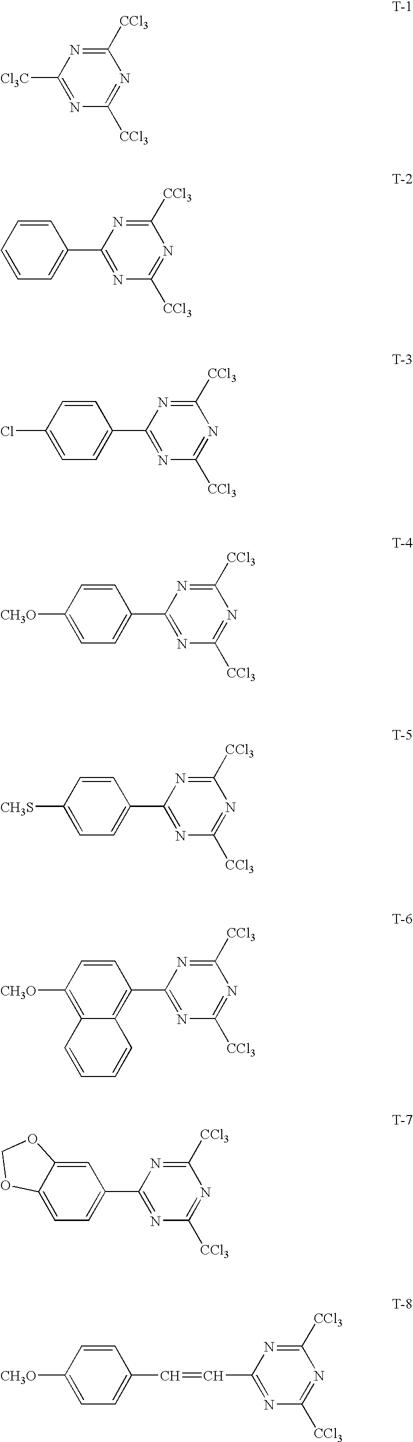

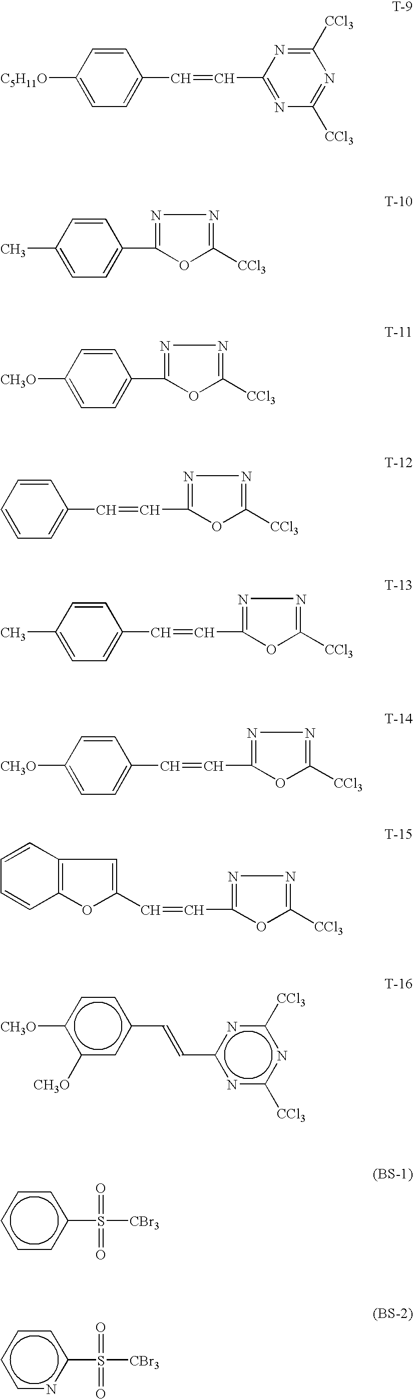

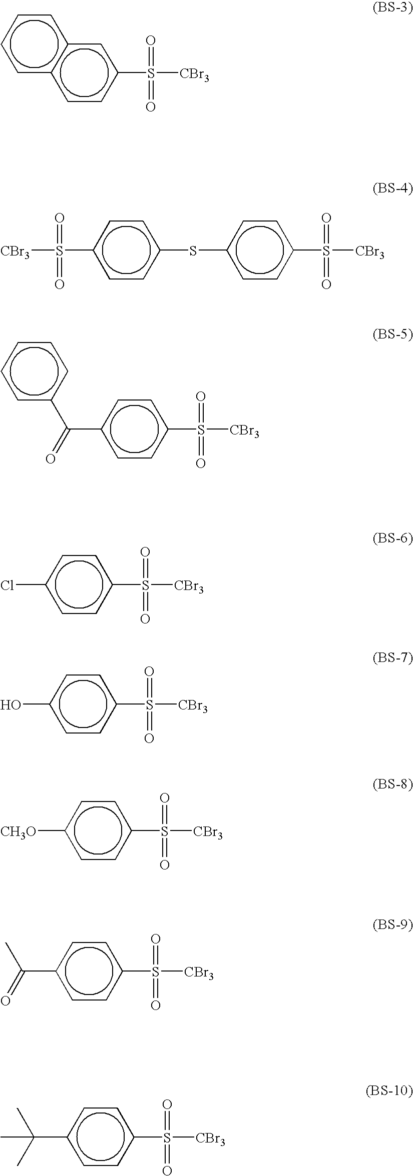

A compound which sensitizes the aforementioned photopolymerization initiator (hereinafter also referred to as a sensitizing compound, sensitizer or sensitizing pigment) is contained in the photocurable photosensitive layer as claimed in the present invention. A sensitizing compound having a peak sensitivity in the light wavelength region of 400 to 430 nm or 750 to 1100 and absorbing light at this wavelength region is preferable for the compound which sensitizes the photopolymerization initiator. Examples of compounds that increase sensitivity in the wavelength region of 400 to 430 nm include cyanine-based pigments; coumarin-based compounds described in, for example, Japanese Unexamined Patent Publications Nos. H7-271284 and H8-29973; carbanol-based compounds described in, for example, Japanese Unexamined Patent Publication Nos. H9-230913 and 2001-42524; carbomerocyanine-based compounds described in, for example, Japanese Unexamined Patent Publications Nos. H8-262715, H8-272096 and H9-328505; aminobenzilideneketone-based pigments described in, for example, Japanese Unexamined Patent Publications Nos. H4-194857, H6-295061, H7-84863, H8-220755, H9-80750 and H9-236913; pyrromethene-based pigments described in, for example, Japanese Unexamined Patent Publications Nos. H4-184344, H6-301208, H7-225474, H7-5685, H7-281434 and H8-6245; styryl-based pigments described in, for example, Japanese Unexamined Patent Publication No. H9-80751; and (thio)pyrylium-based compounds. Among these, cyanine-based pigments, coumarin-based compounds or thio(pyrylium)-based compounds are preferable. Examples of cyanine-based pigments that can be used preferably are indicated below.

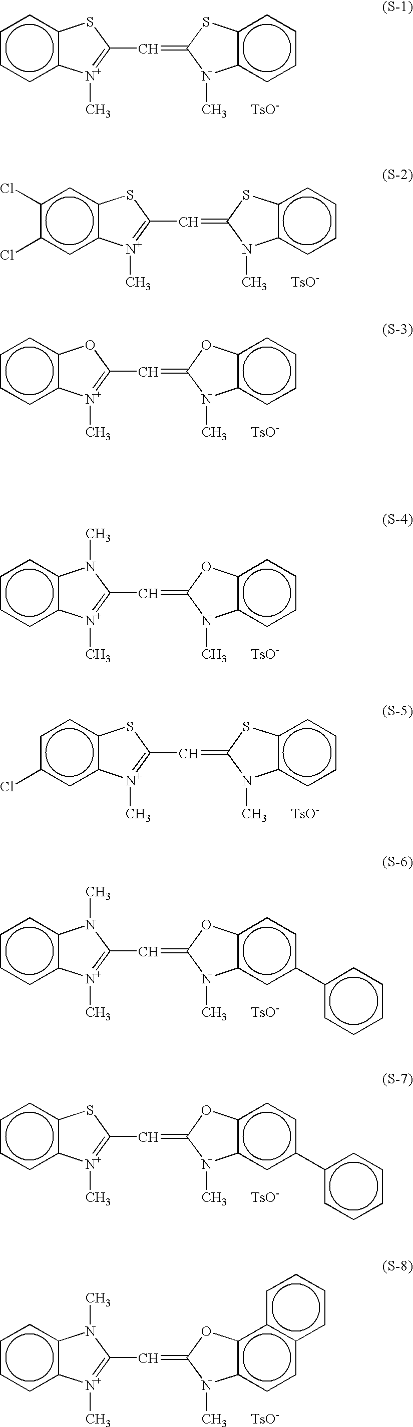

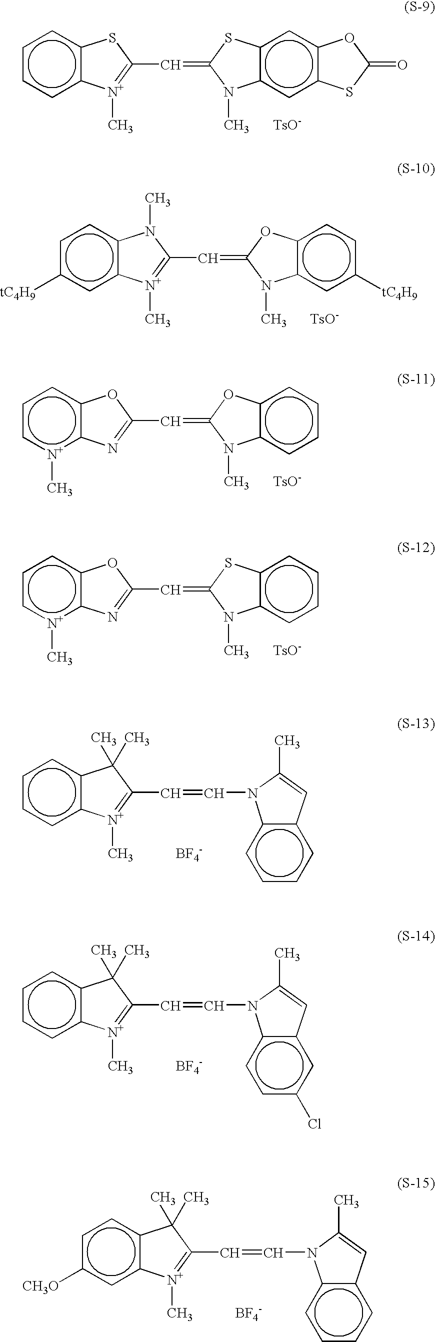

Examples of preferable coumarin-based compounds that can be used to increase sensitivity in the wavelength region of 400 to 430 nm are indicated below.

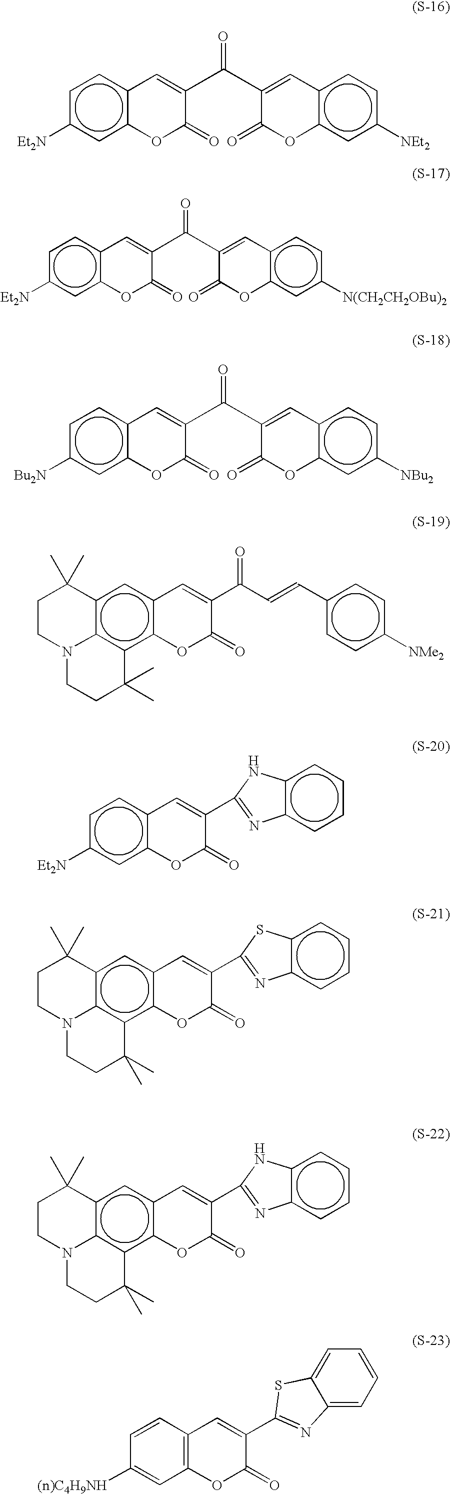

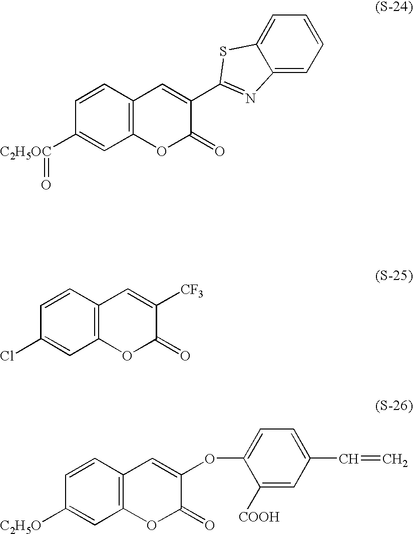

Examples of preferable (thio)pyrylium-based compounds that can be used to increase sensitivity in the wavelength region of 400 to 430 nm are indicated below.

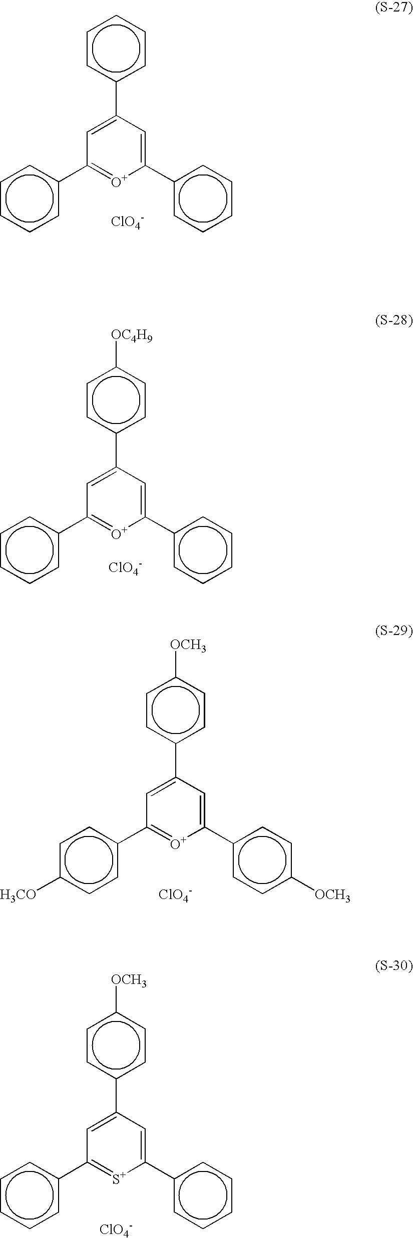

Examples of compounds which increase sensitivity in the wavelength region of 750 to 1100 nm include cyanine-based pigments, porphyrin, spiro compounds, ferrocene, fluorine, fulgide, imidazole, perylene, phenazine, phenothiazine, polyene, azo-based compounds, diphenylmethane, triphenylmethane, polymethine acridine, coumarin, ketocoumarin, quinacridone, indigo, styryl, squarylium-based compounds and (thio)pyrylium-based compounds, while compounds described in European Patent No. 0,568,993, U.S. Pat. No. 4,508,811 and U.S. Pat. No. 5,227,227 can also be used.

Preferable examples of compounds which increase sensitivity in the wavelength region of 750 to 1100 nm (near infrared light) are indicated below.

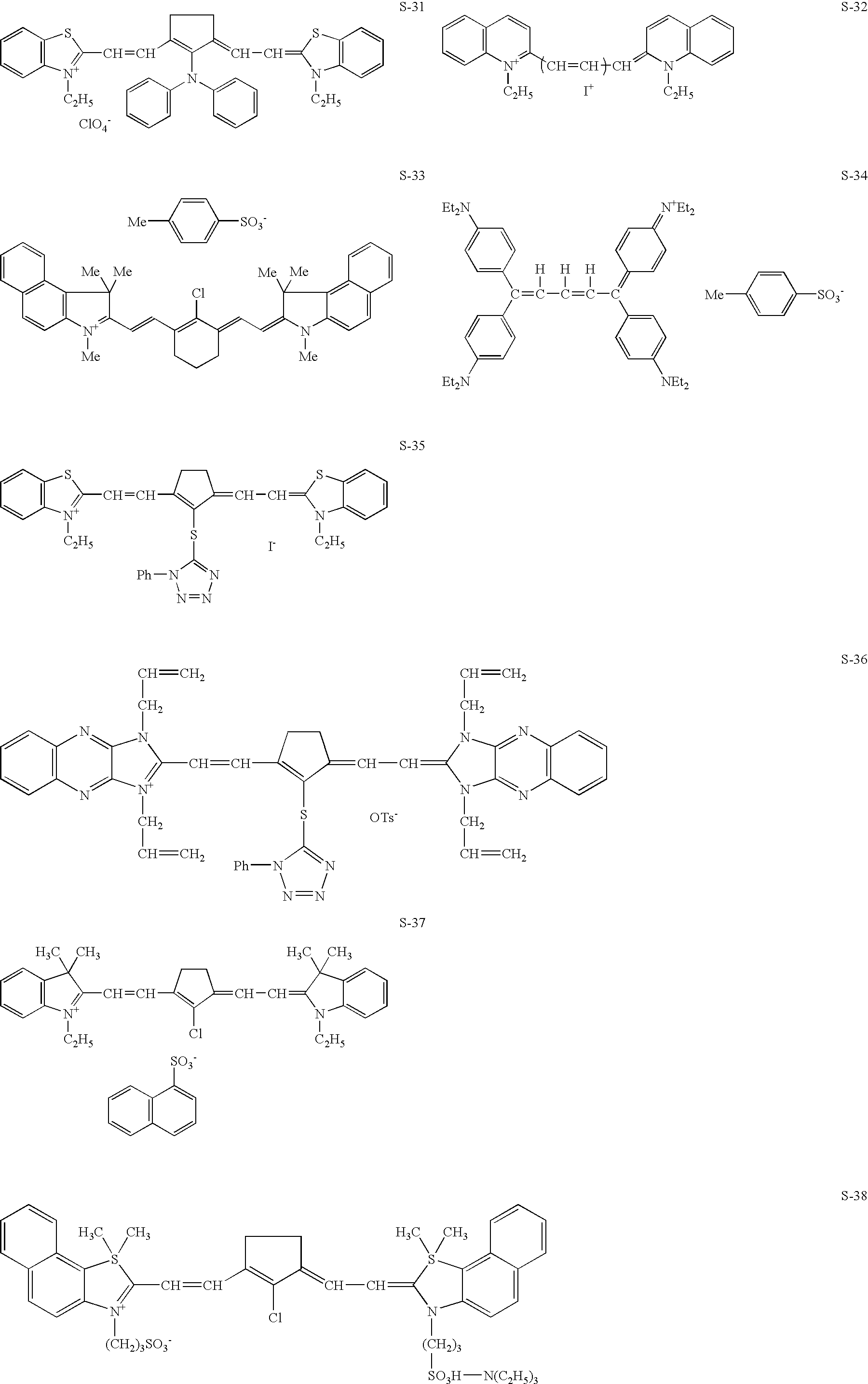

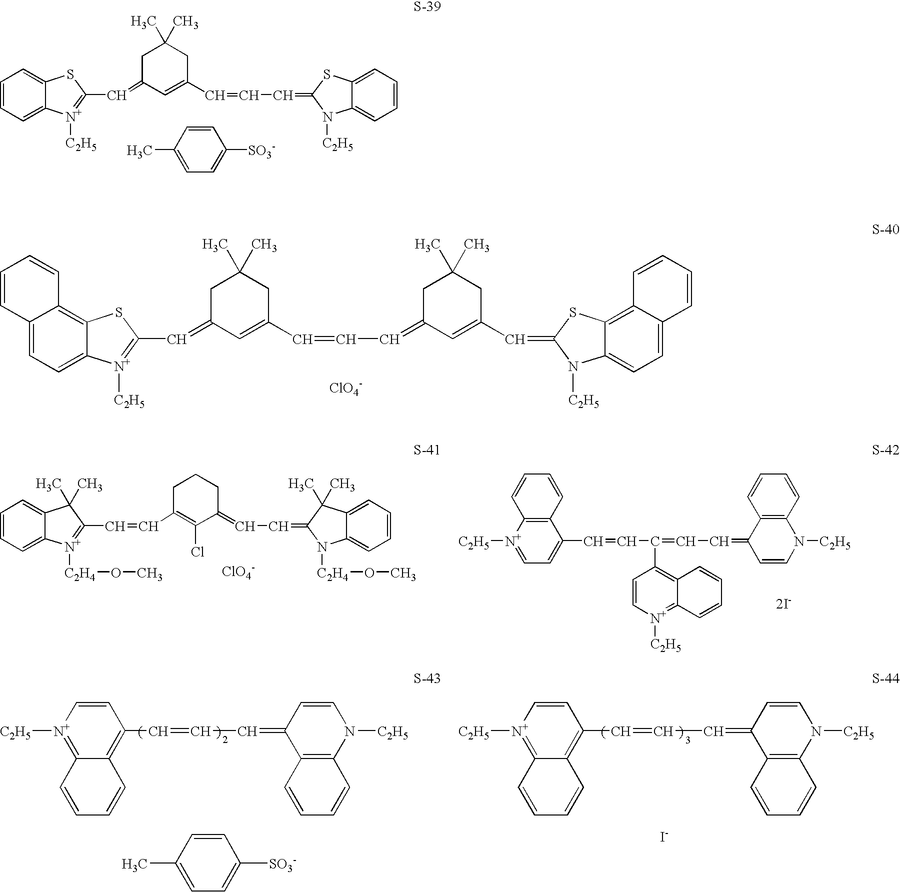

In the present invention, a polyfunctional monomer can also be contained in the photocurable photosensitive layer as necessary. Examples of such polyfunctional monomers include polyfunctional acrylic-based monomers such as 1,4-butanediol diacrylate, 1,6-hexanediol diacrylate, neopentyl glycol diacrylate, tetraethylene glycol diacrylate, tris-acryloyloxyethyl isocyanurate, tripropylene glycol diacrylate, trimethylolpropane triacrylate, pentaerythritol triacrylate or pentaerythritol tetraacrylate. In addition, various types of polymers containing an acryloyl group or methacryloyl group can also be contained in the photocurable photosensitive layer as necessary, and examples of such polymers include polyester (meth)acrylate, urethane (meth)acrylate and epoxy(meth)acrylate.

In addition to the essential components previously described, various dyes or pigments may be added to the photocurable photosensitive layer for the purpose of enhancing image visibility, and inorganic fine particles or organic fine particles may be added to the photocurable photosensitive layer for the purpose of preventing blocking of the photosensitive composition.

Moreover, with respect to long-term storage, a polymerization inhibitor may be added to the photocurable photosensitive layer to prevent a curing reaction in a dark location attributable to thermal polymerization. Various known types of phenol compounds and the like can be used as polymerization inhibitors preferably used for this purpose.

Preferable ranges exist for the ratios of the polymer, photopolymerization initiator and sensitizing compound in the photocurable photosensitive layer. The photopolymerization initiator is preferably within the range of 0.01 to 0.5 parts by weight based on 1 part by weight of the polymer. The sensitizing compound is preferably within the range of 0.001 to 0.1 part by weight based on 1 part by weight of the polymer.

In the case of using the photocurable photosensitive layer in a photosensitive lithographic printing plate material, the dry solid applied amount of the photocurable photosensitive layer itself is preferably within the range of 0.3 to 10 g/m² in terms of the dry weight on the hydrophilic layer. Moreover, a range of 0.5 to 3 g/m² of the dry solid applied amount is extremely preferable for demonstrating favorable resolution and considerably improving printing wear resistance. The photocurable photosensitive layer can be formed by preparing a solution consisting of a mixture of the various aforementioned elements, applying the solution to the hydrophilic layer using various known coating methods, and drying.

In the photosensitive lithographic printing plate material of the present invention, a protective layer is further preferably provided on the photocurable photosensitive layer. The protective layer has the preferable effects of preventing infiltration of low molecular weight compounds such as oxygen and basic substances present in the atmosphere, which inhibit the image forming reaction in the photocurable photosensitive layer induced by exposure, thereby further improving sensitivity to light exposure in air. Moreover, the protective layer can also be expected to demonstrate the effect of protecting the surface of the photocurable photosensitive layer from scratches. Thus, desirable properties of such a protective layer consist of having low permeability to low molecular weight substances such as oxygen, having superior mechanical strength, having superior adhesion with the photocurable photosensitive layer without substantially inhibiting transmission of light used for exposure, and being able to be easily removed in a developing step following exposure. In the water-developable photosensitive lithographic printing plate material of the present invention, since removal of the protective layer and unexposed areas of the photocurable photosensitive layer can be simultaneously carried out in the water development process, the present invention is characterized by not particularly requiring a protective layer removal step. Moreover, although the polymer contained in the photocurable photosensitive layer as previously described is water-soluble so that there may be problems such as adsorption of moisture in the air by the photocurable photosensitive layer thereby causing blocking or changes in sensitivity during storage, by providing a protective layer onto the photocurable photosensitive layer, these problems relating to blocking and changes in sensitivity can be resolved. In addition, in the case of recording using a blue-violet laser diode in a wavelength region of 400 to 430 nm in particular, since laser output thereof is typically weaker than that of a near infrared laser diode, a photocurable photosensitive layer is required that has particularly high sensitivity. In such cases, since sensitivity can be further improved by providing the protective layer, the protective layer can be applied particularly preferably.

These types of contrivances relating to a protective layer have been made in the past, and are described in detail in, for example, U.S. Pat. No. 3,458,311 and Japanese Unexamined Patent Publication No. S55-49729. A water-soluble polymer compound having comparatively higher crystallinity can be used for the material able to be used in the protective layer, specific known examples of which include water-soluble polymer compounds such as polyvinyl alcohol, polyvinyl pyrrolidone, acidic celluloses, gelatine, gum Arabic and polyacrylic acid. Among these, the use of polyvinyl alcohol as the main component of a protective layer yields the most favorable results in terms of basic properties such as oxygen blocking or development removability. A portion of the polyvinyl alcohol used in the protective layer may be substituted with an ester, ether or acetal provided it still contains non-substituted vinyl alcohol units for providing the required oxygen blocking and water solubility. A portion thereof may also be similarly substituted with other copolymer components. The dry solid applied amount of the protective layer when applying the protective layer is preferably within the range of 0.1 to 10 g/m², and preferably within the range of 0.2 to 2 g/m² in terms of the dry weight on the photocurable photosensitive layer. The protective layer can be formed by applying to the photocurable photosensitive layer using various known coating methods, and drying.

In the case of using a material comprising a support, a hydrophilic layer formed on the support, and a photocurable photosensitive layer formed on the hydrophilic layer as described above as a printing plate, a pattern is formed by subjecting to contact exposure or laser scanning exposure to form crosslinking network in the exposed area, and eluting the unexposed area with water since solubility to water in the exposed area decreases.

In the present invention, water used for water development may be pure water or water containing various types of inorganic or organic ionic compounds, and may be water containing sodium, potassium, calcium or magnesium ions and the like. The water may also contain solvents in the form of various types of alcohols such as methanol, ethanol, propanol, isopropanol, ethylene glycol, propylene glycol, methoxyethanol or polyethylene glycol. In the case of using dampening water on a printing press for on-press development, various types of commercially available dampening water can be used. The pH of the dampening water is preferably within the range of about 4 to 10. The dampening water may contain a solvent in the form of various types of alcohols such as methanol, ethanol, propanol, isopropanol, ethylene glycol, propylene glycol, methoxyethanol or polyethylene glycol. Alternatively, development can also be carried out using various types of commercially available gum solutions, and these solutions are preferable for the purpose of protecting the plate surface from soiling by fingerprints and the like.

The photosensitive lithographic printing plate material obtained in the present invention can be used for laser exposure in the wavelength region of 750 to 1100 nm and more preferably in the vicinity of 830 nm. The photosensitive lithographic printing plate material obtained in the present invention can also be used for blue-violet laser exposure in the wavelength region of 400 to 430 nm and more preferably in the vicinity of 405 nm.

The following Examples provide a more detailed explanation of the invention, but the present invention is not limited to these Examples. Parts and percentages in Examples are based on weight. Compound numbers refer to those numbers used hereinbefore.

### EXAMPLES

### Examples 1 to 9

### Support

A polyethylene terephthalate film with an undercoating layer of vinylidene chloride and gelatin being sequentially laminated, and having a thickness of 100 μm was used as a support.

### Hydrophilic Layer

A hydrophilic layer having the composition indicated below was formed on the aforementioned support. The hydrophilic layer was applied to the support using a wire bar so that the applied amount thereof was 2 g/m² in terms of the dry weight. The hydrophilic layer was then dried by heating for 20 minutes with a dryer at 80° C. The sample was further dried by heating for 3 days in a dryer at 40° C., which were then supplied to application of a photocurable photosensitive layer.

Composition of Hydrophilic Layer-Coating Solution

| | |
|---|---|
| Water-soluble polymer (Table 1) solution | 10 g |
| (concentration: 10%) | |
| Colloidal silica (Snowtex RS-S, Nissan Chemical | 10 g |
| Industries, Ltd.) (concentration: 20%) | |
| Crosslinking agent (Table 1) | 0.2 g |
| Pure water | 10 g |

TABLE 1

| Example | Water-soluble Polymer | Crosslinking Agent |
|---|---|---|
| 1 | Polyacrylamide | (M-2) |
| 2 | Hydroxypropyl cellulose | (M-2) |
| 3 | (S-1) | (E-3) |
| 4 | (S-2) | (E-3) |
| 5 | (S-3) | (H-2) |
| 6 | (S-4) | Self-emulsifying isocyanate |
| | | (Duranate WB40) |
| 7 | (A-5) | (E-3) |
| 8 | (A-6) | (E-4) |
| 9 | (A-8) | (E-7) |

### Photocurable Photosensitive Layer

A photocurable photosensitive layer-coating solution having composition indicated below was applied to the hydrophilic layer produced in the manner described above to form a photocurable photosensitive layer. The photocurable photosensitive layer was applied using a wire bar so that the applied amount thereof was 1 g/m² in terms of the dry weight. The applied photocurable photosensitive layer was then dried by heating for 10 minutes in a dryer at 80° C.

Composition of Photocurable Photosensitive Layer-Coating Solution

| | | |
|---|---|---|
| Polymer (SP-8) solution (concentration: 25%) | 4 | g |
| Photopolymerization initiator (BC-6) | 0.1 | g |
| Photopolymerization initiator (T-8) | 0.05 | g |
| Sensitizing pigment (S-38) | 0.03 | g |
| Victoria blue (coloring dye) | 0.02 | g |
| Dioxane | 9 | g |
| Ethanol | 1 | g |

### Exposure Test

Printing plate materials of Examples 1 to 9, comprising the photocurable photosensitive layers and hydrophilic layers as provided in the manner described above, were subjected to an exposure test in the manner described below. Exposure was carried out by using PT-R4000 (Dainippon Screen Mfg. Co., Ltd.) equipped with a laser having a light wavelength of 830 nm for use in aluminum printing plates. In order to carry out lithography using this device, the aforementioned printing plate materials were mounted onto a 0.24 mm thick aluminum plate and fixed using cellophane tape with the photocurable photosensitive layer being outside. Exposure energy was set to about 100 mJ/cm² on the film surface, and lithography was carried out at a drum rotating speed of 1000 rpm. For the test image, a halftone dot gradation pattern equivalent to 2400 dpi/175 lpi and line with 10 to 100 μm width were output followed by evaluation of resolution mentioned hereinbelow.

### Water Developability Test

Each of the printing plate materials of Examples 1 to 9, on which lithography has been carried out as described above, was immersed for 10 seconds in water adjusted to 20° C. followed by gently wiping the surface with a sponge to remove unexposed areas of the photocurable photosensitive layer. At this time, as evaluation criteria of water developability, ∘ means the case in which the unexposed areas of the photocurable photosensitive layer were completely removed, Δ means the case in which residual of the unexposed areas of the photocurable photosensitive layer was observed slightly, and X means the case in which water developability was clearly poor and a residual layer was remained or poor development occurred. Moreover, resolution was evaluated only in cases in which water developability was evaluated as ∘. As evaluation criteria of resolution, ∘ means the case in which fine lines with 10 μm width and halftone dots with dot area percentage of 1% were clearly reproduced, Δ means the case in which fine lines with 10 μm width and halftone dots with dot area percentage of 1% were partially missing but lines with 20 μm or more width and halftone dots with dot area percentage of 2% or more were clearly reproduced, and X means the case in which reproducibility was poorer than the above cases.

### Printability Test

Printing wear resistance, water retention ability and ink removability of the printing plate materials were evaluated to evaluate printability of the printing plate materials. Ryobi 560 sheet-fed offset printing press was used for the printing press, New Champion F Gloss 85 Type F from DIC Corp. was used for the printing ink, and a commercially available dampening solution for pre-sensitized plate in the form of Toho Etching solution diluted to 1% was used for the dampening water. 30,000 sheets were printed. Printing wear resistance, as a parameter of printability, was evaluated in terms of the number of sheets printed until minute halftone dots and fine lines began to be missing from the test image. As evaluation criteria of water retention ability, ∘ means the case in which there was no scumming throughout printing, Δ means the case in which scumming occurred in the early or late stage of printing, and X means the case in which scumming was observed throughout the course of printing. For ink removability, ink removability was evaluated in printing from the time the dampening water supply dial was returned to the normal value after dampening solution was wiped off and the entire plate surface was covered with ink followed by printing. For evaluation criteria of the ink removability, ∘ means the case in which scumming disappeared within the first 50 sheets printed, Δ means the case in which scumming disappeared at 50 to less than 100 sheets, and X means the case in which scumming disappeared only after 100 or more sheets were printed.

### On-Press Developability Test

On-press developability of the printing plate materials was evaluated separately from the evaluation of printability as described above. While using the same printing plate as above except that unexposed areas of the photocurable photosensitive layer had not been removed from the plate, and using the same printing press, ink and dampening water, the ink supply was set to zero at the start of printing and dampening water was adequately supplied to the plate surface, after that, printing was started. For evaluation criteria of the on-press developability, ∘ means the case in which normal printed matter free of scumming were obtained within less than 100 sheets printed, Δ means the case in which normal printed matter free of scumming was obtained at from 100 to less than 200 sheet, and X means the case in which normal printed matter free of scumming was obtained only after 200 or more sheets were printed.

The results of the evaluations are summarized in Table 2.

TABLE 2

| | | | | Water | | |
|---|---|---|---|---|---|---|
| | Water | | Printing wear | retention | Ink | On-press |
| Example | developability | Resolution | resistance | ability | removability | developability |
| 1 | ◯ | ◯ | 21000 | ◯ | ◯ | ◯ |
| 2 | ◯ | ◯ | 20000 | ◯ | ◯ | ◯ |
| 3 | ◯ | ◯ | 30000 | ◯ | ◯ | ◯ |
| 4 | ◯ | ◯ | 30000 | ◯ | ◯ | ◯ |
| 5 | ◯ | ◯ | 26000 | ◯ | ◯ | ◯ |
| 6 | ◯ | ◯ | 25000 | ◯ | ◯ | ◯ |
| 7 | ◯ | ◯ | 30000 | ◯ | ◯ | ◯ |
| 8 | ◯ | ◯ | 30000 | ◯ | ◯ | ◯ |
| 9 | ◯ | ◯ | 30000 | ◯ | ◯ | ◯ |

As can be seen in Table 2, all of the examples demonstrated favorable printing wear resistance of 20,000 to 30,000 sheets, while also demonstrating favorable water developability, resolution, water retention ability, ink removability and on-press developability.

### Comparative Examples 1 to 6

### Support

In the same manner as Examples 1 to 9, a polyethylene terephthalate film with an undercoating layer of vinylidene chloride and gelatin being sequentially laminated, and having a thickness of 100 μm was used as a support.

### Hydrophilic Layer

A hydrophilic layer having the composition indicated below was formed on the aforementioned support. The hydrophilic layer was applied to the support using a wire bar so that the applied amount thereof was 2 g/m² in terms of the dry weight. The hydrophilic layer was then dried by heating for 20 minutes with a dryer at 80° C. The sample was further dried by heating for 3 days in a dryer at 40° C., which were then supplied to application of a photocurable photosensitive layer.

Composition of Hydrophilic Layer-Coating Solution

| | |
|---|---|
| Water-soluble polymer (Table 3) solution | Amount in Table 3 |
| (concentration: 10%) | |
| Colloidal silica (Snowtex S, Nissan Chemical | 10 g |
| Industries, Ltd.) (spherical silica) | |
| (concentration: 20%) | |
| Crosslinking agent (Table 3) | Amount in Table 3 |
| Pure water | 10 g |

TABLE 3

| | | | | Amount |
|---|---|---|---|---|
| Comparative | Water-soluble | Amount | Crosslinking | added |
| Example | Polymer | added (g) | Agent | (g) |
| 1 | Polyacrylamide | 10 | None | — |
| 2 | Polyvinyl alcohol | 4 | Glutaraldehyde | 0.1 |
| | (PVA235, Kuraray | | | |
| | Co., Ltd.) | | | |
| 3 | (S-1) | 40 | None | — |
| 4 | (S-1) | 40 | (E-3) | 0.8 |
| 5 | (S-1) | 4 | (E-3) | 0.08 |
| 6 | Polyacrylic acid | 20 | None | — |

The same photocurable photosensitive layer coating solution as that of Examples 1 to 9 was applied in the same manner as Examples 1 to 9 to the comparative hydrophilic layers formed on the support as produced above followed by drying to produce printing plate materials of Comparative Examples 1 to 6. These Comparative Examples were evaluated in the same manner as Examples 1 to 9 and the results shown in Table 4 were obtained.

TABLE 4

| | | | Printing | Water | | |
|---|---|---|---|---|---|---|
| Comparative | Water | | wear | retention | Ink | On-press |
| Example | developability | Resolution | resistance | ability | removability | developability |
| 1 | ◯ | X | 1000 | Δ | Δ | Δ |
| 2 | ◯ | Δ | 10000 | Δ | Δ | Δ |
| 3 | ◯ | X | 5000 | X | Δ | X |
| 4 | ◯ | Δ | 15000 | ◯ | Δ | ◯ |
| 5 | ◯ | Δ | 10000 | Δ | Δ | Δ |
| 6 | ◯ | X | 5000 | X | X | Δ |

As seen from the results in Table 4, satisfactory results were unable to be obtained for each of Comparative Examples 1 to 6 with respect to resolution, printing wear resistance, water retention ability, ink removability or on-press developability.

### Comparative Examples 7 to 9

Printing plate materials of Comparative Examples 7 to 9 were prepared in the same manner as Example 1 except for using each polymer indicated below in stead of the polymers used in Examples 1 to 9 for the polymer contained in the photocurable photosensitive layer-coating solution. The printing plate materials of Comparative Examples 7 to 9 were evaluated in the same manner as Examples 1 to 9, and the results are shown in Table 5. The numbers shown in the following chemical formulae represent the weight ratio of each repeating unit in the polymers.

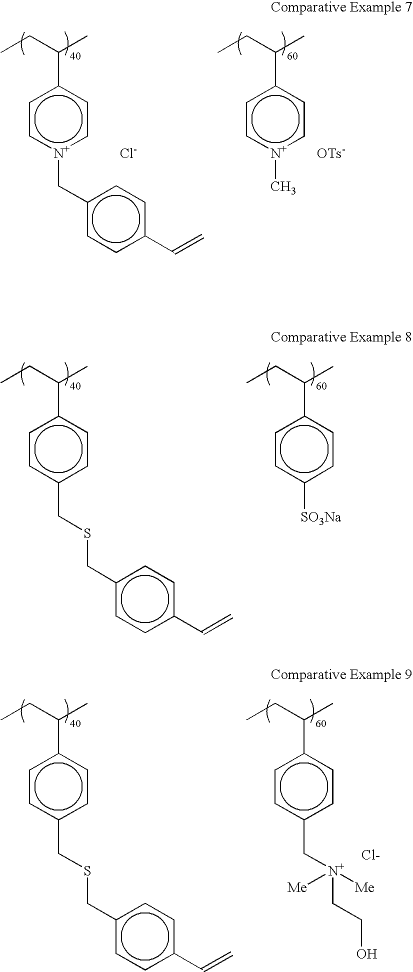

TABLE 5

| | | | Printing | Water | | |
|---|---|---|---|---|---|---|
| Comparative | Water | | wear | retention | Ink | On-press |
| Example | developability | Resolution | resistance | ability | removability | developability |
| 7 | Δ | X | 10000 | Δ | Δ | Δ |
| 8 | ◯ | Δ | 10000 | ◯ | ◯ | ◯ |
| 9 | ◯ | X | 10000 | ◯ | ◯ | ◯ |

As seen from the results in Table 5, satisfactory results were unable to be obtained for each of Comparative Examples 7 to 9 with respect to water developability, resolution, printing wear resistance, water retention ability, ink removability or on-press developability.

### Examples 10 to 13 and Comparative Examples 10 to 12

The printing plate materials of Examples 10 to 13 and Comparative Examples 10 to 12 were prepared in the same manner as Example 1 with the exception of changing the ratios of colloidal silica and water-soluble polymer as well as the type of colloidal silica in composition of the hydrophilic layer coating solution indicated below. Each of the evaluations was then carried out in the same manner as Example 1.

Composition of Hydrophilic Layer-Coating Solution

| | |
|---|---|
| Water-soluble polymer (S-1) solution | Amount X in Table 6 (g) |
| (concentration: 10%) | |
| Colloidal silica (Snowtex, Nissan | Amount Y in Table 6 (g) |
| Chemical (concentration: 20%) | |
| Crosslinking agent (E-3) | X/10 (g) |
| Pure water | 10 g |

TABLE 6

| | X (g) | Y (g) | Type of colloidal silica |
|---|---|---|---|
| Example 10 | 10 | 5 | PS-S (necklace) |
| Example 11 | 10 | 15 | PS-S (necklace) |
| Example 12 | 10 | 5 | S (spherical) |
| Example 13 | 10 | 15 | S (spherical) |
| Comparative Example 10 | 10 | 3 | PS-S (necklace) |
| Comparative Example 11 | 10 | 20 | PS-S (necklace) |
| Comparative Example 12 | 10 | 0 | None |

The results of the evaluations are shown in Table 7. Each of the Examples 10 to 13 yielded favorable results, while Comparative Examples 10 to 12 were all inferior in terms of resolution, printing wear resistance, water retention ability, ink removability and on-press developability.

TABLE 7

| | | | Printing | Water | | |
|---|---|---|---|---|---|---|
| | Water | | wear | retention | Ink | On-press |
| | developability | Resolution | resistance | ability | removability | developability |
| Example 10 | ◯ | ◯ | 25000 | ◯ | ◯ | ◯ |
| Example 11 | ◯ | ◯ | 25000 | ◯ | ◯ | ◯ |
| Example 12 | ◯ | ◯ | 20000 | ◯ | ◯ | ◯ |
| Example 13 | ◯ | ◯ | 22000 | ◯ | ◯ | ◯ |
| Comparative | ◯ | Δ | 10000 | Δ | Δ | Δ |
| Example 10 | | | | | | |
| Comparative | ◯ | Δ | 15000 | Δ | Δ | Δ |
| Example 11 | | | | | | |
| Comparative | ◯ | X | 1000 | X | X | X |
| Example 12 | | | | | | |

### Examples 14 to 22

The photosensitive printing plate materials of Examples 14 to 22 were prepared in the same manner as Examples 1 to 9 with the exception of using an aluminum plate for use in offset printing with a surface-roughened anodic oxide coating being provided for the printing plate support. The printing plate materials were placed on PT-R4000 and lithography was carried out in the same manner as Examples 1 to 9 followed by carrying out a water developability test, printability test (carried out on up to 100,000 sheets) and an on-press developability test in the same manner as in Examples 1 to 9. The results are summarized in Table 8.

TABLE 8

| | | | | Water | | |
|---|---|---|---|---|---|---|
| | Water | | Printing wear | retention | Ink | On-press |
| Example | developability | Resolution | resistance | ability | removability | developability |
| 14 | ◯ | ◯ | 50000 | ◯ | ◯ | ◯ |
| 15 | ◯ | ◯ | 50000 | ◯ | ◯ | ◯ |
| 16 | ◯ | ◯ | 100000 | ◯ | ◯ | ◯ |
| | | | or more | | | |
| 17 | ◯ | ◯ | 100000 | ◯ | ◯ | ◯ |
| | | | or more | | | |
| 18 | ◯ | ◯ | 100000 | ◯ | ◯ | ◯ |
| | | | or more | | | |
| 19 | ◯ | ◯ | 100000 | ◯ | ◯ | ◯ |
| | | | or more | | | |
| 20 | ◯ | ◯ | 100000 | ◯ | ◯ | ◯ |
| | | | or more | | | |
| 21 | ◯ | ◯ | 100000 | ◯ | ◯ | ◯ |
| | | | or more | | | |
| 22 | ◯ | ◯ | 100000 | ◯ | ◯ | ◯ |
| | | | or more | | | |

As can be seen in Table 8, all of Examples 14 to 22 demonstrated favorable printing wear resistance of 50,000 sheets or more, while also demonstrating favorable water developability, resolution, water retention ability, ink removability and on-press developability.

### Comparative Example 13

The printing plate material of Comparative Example 13 was prepared by using an aluminum plate for use in offset printing with a surface-roughened anodic oxide coating being provided for the printing plate support, and applying the photocurable photosensitive layer-coating solution used in Examples 1 to 9 directly to the surface of the aluminum plate without providing a hydrophilic layer on the support. When this was evaluated in the same manner as Examples 1 to 9, there was prominent scumming during evaluation of printing and normal printed matter was unable to be obtained.

### Examples 23 to 32

The photosensitive lithographic printing plate materials 23 to 32 were prepared respectively in the same manner as Examples 1 to 9 with the exception of replacing the sensitizing pigments contained in the photocurable photosensitive layer-coating solution of Examples 1 to 9 with the compounds shown in Table 9 and applying the photocurable photosensitive layer to the hydrophilic layer produced in Example 3. To evaluate the sensitivity of the photocurable photosensitive layer, ultraviolet light from an ultra-high-voltage ultraviolet lamp was radiated onto the photosensitive lithographic printing plate materials with passing through an interference filter allowing only the transmission of light with a wavelength of 405 nm. The minimum amount of exposure energy at which the photocurable photosensitive layer is cured resulting in making the layer water insoluble was determined using a step wedge having a concentration difference of 0.15. Here, development was carried out by immersing the printing plate materials in a water bath controlled to 30° C. for 10 seconds following exposure and then rubbing the surface with a sponge while rinsing with tap water. The printing plate materials were then dried after developing. The image density of the exposed area was measured using a reflection densitometer, the minimum amount of exposure at which a residual layer was formed was detected, and that value was used as an indicator of sensitivity. The results relating to sensitivity determined in this manner are also shown in Table 9. Moreover, as another embodiments of the printing plate materials of Comparative Examples 23 to 32, printing plate materials having a protective layer were also produced by applying a 10% aqueous solution of polyvinyl alcohol (PVA-105, Kuraray Co., Ltd.) at a dry applied amount of 0.7 g/m² to the uppermost layer of each of the photosensitive lithographic printing plate materials 32 to 32 to form a protective layer followed by drying. The sensitivities of these embodiments are also shown in Table 9. As can be seen in Table 9, it was revealed that cyanine-based pigments, coumarin-based compounds and (thio)pyrylium-based compounds imparted high sensitivity for light having a wavelength of 405 nm, and even higher sensitivity was achieved by providing a protective layer. Moreover, for an accelerated storage test, sensitivity after allowing each of the photosensitive lithographic printing plate materials to stand for 9 hours in a dryer at 80° C. was similarly evaluated. As a result, no changes in sensitivity were observed for any of the photosensitive lithographic printing plate materials having a protective layer, while all of the printing plate material having no protective layer demonstrated decrease in sensitivity of about 20%.

TABLE 9

| | Sensitizing | Sensitivity | Sensitivity as having protective |
|---|---|---|---|
| Example | agent | (μJ/cm²) | layer (μJ/cm²) |
| 23 | S-1 | 250 | 120 |
| 24 | S-3 | 250 | 120 |
| 25 | S-6 | 280 | 140 |
| 26 | S-10 | 250 | 120 |
| 27 | S-16 | 150 | 80 |
| 28 | S-18 | 150 | 80 |
| 29 | S-21 | 200 | 100 |
| 30 | S-22 | 180 | 100 |
| 31 | S-27 | 150 | 80 |
| 32 | S-30 | 150 | 80 |

### Example 33

Using the photosensitive lithographic printing plate materials having a protective layer as prepared in Examples 23, 27 and 31, test patterns were lithographed on each printing plate material using a blue-violet laser diode (output: 80 mW) emitting light at 405 nm and setting the plate surface exposure energy to 120 μL/cm². Subsequently, water developability and printability were evaluated in the same manner as Examples 1 to 9. All of the photosensitive lithographic printing plate materials demonstrated favorable water developability, demonstrated favorable printing wear resistance of 30,000 sheets, and demonstrated favorable water retention ability in the printing evaluation.

### Example 34

A storage test in a high-humidity atmosphere was carried out using the photosensitive lithographic printing plate material having a protective layer and the photosensitive lithographic printing plate material having no protective layer, both prepared in Example 23. Here, the presence of blocking and changes in sensitivity were measured after laminating 10 sheets each of each material and storing for 1 month in an atmosphere at a relative humidity of 85%. As a result, mild blocking and a 20% decrease in sensitivity were observed for the material having no protective layer, while there was no blocking or changes in sensitivity for the material provided having a protective layer.

### INDUSTRIAL APPLICABILITY

According to the present invention, a highly sensitive photosensitive lithographic printing plate material capable of being used in a CTP system, which allows on-press development and/or development with water and has superior printability, can be obtained. In addition, a plastic film-based printing plate and aluminum-based printing plate can be obtained that can be developed either on a printing press or with water in a CTP printing system using a scanning exposure device that uses a laser diode emitting light in the wavelength region of 750 to 1100 nm or a laser emitting light in the wavelength region of 400 to 430 nm.

1. A water-developable photosensitive lithographic printing plate material comprising:
a support;
on the support, a hydrophilic layer containing a water-soluble polymer, a crosslinking agent which forms a crosslinking network with the water-soluble polymer, and colloidal silica, wherein the weight ratio of the water-soluble polymer to the colloidal silica is within the range of 1:1 to 1:3; and,
on the hydrophilic layer, a photocurable photosensitive layer containing:
a polymer having a sulfonic acid group and a vinylphenyl group in a side chain wherein the vinylphenyl group is attached to a main chain through a linking group containing a hetero ring,
a photopolymerization initiator, and
a compound which sensitizes the photopolymerization initiator.

2. The water-developable photosensitive lithographic printing plate material according to claim 1, wherein the water-soluble polymer is a polymer represented by the following general formula I:
A_{X}B_{100-X} General Formula I
wherein, X represents the percent (%) by weight of a repeating unit A in a copolymer, and represents an arbitrary value of 1 to 40, the repeating unit A represents a repeating unit having as a reactive group thereof a group selected from the group consisting of a carboxyl group, amino group, hydroxyl group and acetoacetoxy group, and the repeating unit B represents a repeating unit having a hydrophilic group required for making the copolymer water-soluble.

3. The water-developable photosensitive lithographic printing plate material according to claim 1, wherein the crosslinking agent is a water-soluble epoxy compound.

4. The water-developable photosensitive lithographic printing plate material according to claim 1, wherein the photopolymerization initiator contains a combination of an organic boron salt and a trihaloalkyl-substituted compound.

5. The water-developable photosensitive lithographic printing plate material according to claim 1, for use in infrared laser exposure in the wavelength region of 750 to 1100 nm.

6. The water-developable photosensitive lithographic printing plate material according to claim 1, for use in blue-violet laser exposure in the wavelength region of 400 to 430 nm.

7. The water-developable photosensitive lithographic printing plate material according to claim 1, wherein the compound which sensitizes the photopolymerization initiator is a cyanine-based pigment, a coumarin-based compound or a (thio)pyrylium-based compound.

8. The water-developable photosensitive lithographic printing plate material according to claim 1, further having a protective layer containing polyvinyl alcohol provided on the photocurable photosensitive layer.

9. The water-developable photosensitive lithographic printing plate material according to claim 2, wherein the crosslinking agent is a water-soluble epoxy compound.

10. The water-developable photosensitive lithographic printing plate material according to claim 2, wherein the photopolymerization initiator contains a combination of an organic boron salt and a trihaloalkyl-substituted compound.

11. The water-developable photosensitive lithographic printing plate material according to claim 3, wherein the photopolymerization initiator contains a combination of an organic boron salt and a trihaloalkyl-substituted compound.

12. The water-developable photosensitive lithographic printing plate material according to claim 2, for use in infrared laser exposure in the wavelength region of 750 to 1100 nm.

13. The water-developable photosensitive lithographic printing plate material according to claim 3, for use in infrared laser exposure in the wavelength region of 750 to 1100 nm.

14. The water-developable photosensitive lithographic printing plate material according to claim 4, for use in infrared laser exposure in the wavelength region of 750 to 1100 nm.

15. The water-developable photosensitive lithographic printing plate material according to claim 2, for use in blue-violet laser exposure in the wavelength region of 400 to 430 nm.

16. The water-developable photosensitive lithographic printing plate material according to claim 3 for use in blue-violet laser exposure in the wavelength region of 400 to 430 nm.

17. The water-developable photosensitive lithographic printing plate material according to claim 4, for use in blue-violet laser exposure in the wavelength region of 400 to 430 nm.

18. The water-developable photosensitive lithographic printing plate material according to claim 2, wherein the compound which sensitizes the photopolymerization initiator is a cyanine-based pigment, a coumarin-based compound or a (thio)pyrylium-based compound.

19. The water-developable photosensitive lithographic printing plate material according to claim 3, wherein the compound which sensitizes the photopolymerization initiator is a cyanine-based pigment, a coumarin-based compound or a (thio)pyrylium-based compound.

20. The water-developable photosensitive lithographic printing plate material according to claim 4, wherein the compound which sensitizes the photopolymerization initiator is a cyanine-based pigment, a coumarin-based compound or a (thio)pyrylium-based compound.
